(19) United States
(12) Patent Application Publication
(10) Pub. No.: US 2009/0314334 A1
(43) Pub. Date: Dec. 24, 2009

(54) ELECTRONIC SUBSTRATE FOR A PHOTOVOLTAIC MODULE

(75) Inventor: Ivan Saha, Chennai (IN)

Correspondence Address: DARBY & DARBY P.C., P.O. BOX 770, Church Street Station, New York, NY, 10008-0770, US

(73) Assignee: MOSER BAER PHOTOVOLTAIC LIMITED, Chennai (IN)

(21) Appl. No.: 12/178,059

(22) Filed: Jul. 23, 2008

(30) Foreign Application Priority Data
Jun. 24, 2008 (IN) 2008/CHE/007139

(51) Int. Cl. H01L 31/042

(52) U.S. Cl. 136/249; 136/256

(57) ABSTRACT

Methods and systems for fabricating a photovoltaic module are provided. One or more conducting pads are formed over a base of an electronic substrate, such that pad spaces are created between adjacent conducting pads. The electronic substrate includes a plurality of path options, and one or more bond pads. The path options are embedded in the base. The bond pads are formed over the base. One or more photovoltaic strips are arranged over the conducting pads. The bond pads provide an interface to connect photovoltaic strips to at least one of the path options. The photovoltaic strips are connected to the bond pads through one or more connectors in series and/or parallel. A plurality of optical vees is placed in the pad spaces between the conductive pads for concentrating solar energy over the photovoltaic strips.

### CROSS REFERENCE TO RELATED APPLICATIONS

This application claims the benefit of Indian Patent Application Number 2008/CHE/007139, filed on Jun. 24, 2008, which is hereby incorporated by reference in its entirety.

### BACKGROUND

The present invention relates, in general, to photovoltaic modules. More specifically, the present invention relates to a method and system for fabricating a photovoltaic module over an electronic substrate.

Photovoltaic cells are large area semiconductor diodes that convert incident solar energy into electrical energy. Photovoltaic cells are often made of silicon wafers. The photovoltaic cells are combined in series and/or parallel to form photovoltaic modules.

Existing photovoltaic modules use silicon wafers as a major component. This makes these photovoltaic modules expensive and difficult to manufacture efficiently on a large scale. Various techniques are employed by replacing silicon with cheap plastic reflective/refractive optics in order to increase the power output and reduce the cost of photovoltaic modules. However, conventional photovoltaic modules are not economical compared to grid electricity, due to higher rejections during manufacturing/quality control processes, low efficiencies owing to requirement of precise assembly process.

Photovoltaic modules have been fabricated by using various techniques. These fabrication techniques usually involve soldering or wiring photovoltaic cells together to form a photovoltaic module. This is time-consuming. Moreover, the soldered points are exposed and are susceptible to damage. Accidental electrical contacts with such points may lead to short circuiting.

In light of the foregoing discussion, there is a need for a photovoltaic module (and a fabrication method and system thereof) that is suitable for mass manufacturing, has ease of manufacturing, has lower cost, requires lesser amount of silicon to produce similar electrical output, and has increased life time compared to conventional low concentrator photovoltaic modules.

### SUMMARY

An object of the present invention is to provide an electronic substrate (fabrication method and system thereof) for use in a photovoltaic module that is suitable for mass manufacturing and has ease of manufacturing compared to conventional low concentrator photovoltaic modules. The electronic substrate should be suitable for use in a photovoltaic module.

Another object of the present invention is to provide an electronic substrate that has lower cost compared to conventional low concentrator photovoltaic modules.

Yet another object of the present invention is to provide a photovoltaic module that requires lesser amount of silicon to produce similar electrical output compared to conventional low concentrator photovoltaic modules.

Still another object of the present invention is to provide a photovoltaic module with increased life time compared to low concentrator photovoltaic modules. An electronic substrate used in the photovoltaic module should be manufactured with embedded inter-connections. This avoids the use of external conductors and further prevents short circuiting of components placed over the electronic substrate.

Embodiments of the present invention provide a photovoltaic module for generating electricity from solar energy. The photovoltaic module includes an electronic substrate for providing mechanical support and electrical connections to the photovoltaic module. The electronic substrate includes a base for providing a plurality of path options. One or more conductive pads are formed over the base, such that pad spaces are created between adjacent conductive pads. Each conductive pad is electrically connected to at least one of the path options.

Further, one or more bond pads are formed over the base. One or more photovoltaic strips are arranged over the conductive pads. The photovoltaic strips may, for example, be formed by dicing a semiconductor wafer. The bond pads provide an interface for connecting the photovoltaic strips to the path options in a predefined manner. The predefined manner may, for example, be a series and/or parallel arrangement, such that electrical output is maximized. The photovoltaic strips are connected to the bond pads through one or more connectors.

One or more optical vees are placed over the pad spaces between the conductive pads, such that a plurality of cavities is formed between adjacent optical vees. The optical vees may be hollow or solid. The optical vees are capable of concentrating solar energy over the photovoltaic strips. In an embodiment of the present invention, the optical vees have a reflective layer or surface, such that sun rays incident on the reflective layer or surface are reflected towards the photovoltaic strips. When the reflected sun rays fall on the photovoltaic strips, electricity is generated by the photoelectric effect.

In another embodiment of the present invention, the optical vees include a first medium and a second medium underlying the first medium. The ratio of the refractive index of the first medium to the refractive index of the second medium is greater than one. Examples of the first medium include, but are not limited to, plastics, glass, acrylics, and transparent polymeric materials. Examples of the second medium include, but are not limited to, air and vacuum. Total internal reflection occurs at a medium boundary between the first medium and the second medium.

One or more concentrating elements are filled in the cavities. These concentrating elements may, for example, be formed by pouring a polymeric material in a fluid state over the cavities. The concentrating elements then take the shape of the cavities in cross-section. In another example, the concentrating elements are formed by re-molding pre-molded concentrating elements made of the polymeric material over the cavities. In yet another example, the concentrating elements made of the polymeric material may be in a pre-molded form. Examples of the polymeric material include, but are not limited to, Ethyl Vinyl Acetate (EVA), silicone, Thermoplastic Poly-Urethane (TPU), Poly Vinyl Butyral (PVB), acrylics, polycarbonates, and synthetic resins.

In an embodiment of the present invention, the photovoltaic module also includes a transparent member positioned over the optical vees. The transparent member is coated with an anti-reflective coating to reduce loss of solar energy incident on the photovoltaic module, in accordance with an embodiment of the present invention. In accordance with an embodiment of the present invention, the transparent member is sealed with the electronic substrate, and the electronic substrate, the photovoltaic strips, the optical vees and the transparent member form the photovoltaic module in an integrated manner.

The electronic substrate can be fabricated with completely automated processes and machines, thereby enabling mass manufacturing. The electronic substrate includes embedded path options. This avoids short circuiting with various components of the photovoltaic module. This, in turn, increases the life time of the photovoltaic module so formed.

In addition, the fabrication of the photovoltaic module involves the similar processes and machines that are required to fabricate conventional low concentrator photovoltaic modules. Therefore, the method of fabrication of the photovoltaic module is easy, quick and cost-effective.

Moreover, the photovoltaic module provides maximized outputs, at appropriate configurations of the photovoltaic strips and appropriate levels of concentration. Therefore, the photovoltaic module requires lesser amount of semiconductor material to generate same electrical output compared to conventional low concentrator photovoltaic modules.

### BRIEF DESCRIPTION OF DRAWINGS

Embodiments of the present invention will hereinafter be described in conjunction with the appended drawings provided to illustrate and not to limit the present invention, wherein like designations denote like elements, and in which:

FIG. 1 illustrates an electronic substrate 100, in accordance with an embodiment of the present invention;

FIG. 2 illustrates how one or more optical vees 202 are placed over electronic substrate 100, in accordance with an embodiment of the present invention;

FIG. 3 FIG. 3 illustrates a view of photovoltaic strips 108 and optical vees 202 arranged over electronic substrate 100, in accordance with an embodiment of the present invention;

FIG. 4 illustrates a top view of electronic substrate 100, in accordance with an embodiment of the present invention;

FIG. 5 illustrates another view of photovoltaic strips 108 and optical vees 202 arranged over electronic substrate 100, in accordance with an embodiment of the present invention;

FIG. 6 shows a view of electronic substrate 100, in accordance with an embodiment of the present invention;

FIG. 7a illustrates a blown-up view of a photovoltaic module 700a, in accordance with an embodiment of the present invention;

FIG. 7b illustrates a blown-up view of a photovoltaic module 700b, in accordance with another embodiment of the present invention;

FIG. 8a illustrates a cross-sectional view of photovoltaic module 700a, in accordance with an embodiment of the present invention;

FIG. 8b illustrates a cross-sectional view of photovoltaic module 700b, in accordance with another embodiment of the present invention;

FIG. 9 is a perspective view illustrating a lay-up of a transparent member 704 over optical vees 202, in accordance with an embodiment of the present invention;

FIG. 10 is a perspective view of a photovoltaic module, in accordance with an embodiment of the present invention;

FIG. 11a illustrates a system 1100a for manufacturing photovoltaic module 700a, in accordance with an embodiment of the present invention;

FIG. 11b illustrates a system 1100b for manufacturing photovoltaic module 700b, in accordance with another embodiment of the present invention;

FIG. 12 is a flow diagram illustrating a method of fabricating an electronic substrate for use in a photovoltaic module, in accordance with an embodiment of the present invention;

FIG. 13 is a flow diagram illustrating a method of fabricating an electronic substrate for use in a photovoltaic module, in accordance with another embodiment of the present invention;

FIG. 14 is a flow diagram illustrating a method for manufacturing a photovoltaic module, in accordance with an embodiment of the present invention;

FIG. 15 is a flow diagram illustrating a method for manufacturing a photovoltaic module, in accordance with another embodiment of the present invention;

FIG. 16 is a flow diagram illustrating a method for manufacturing a photovoltaic module, in accordance with another embodiment of the present invention;

FIG. 17A-D illustrates various methods of fabricating optical vees;

FIG. 18 illustrates a system 1800 for generating electricity from solar energy, in accordance with an embodiment of the present invention;

FIG. 19 illustrates a system 1900 for generating electricity from solar energy, in accordance with another embodiment of the present invention;

FIG. 20 illustrates a method for manufacturing a system for generating electricity from solar energy, in accordance with an embodiment of the present invention; and

FIG. 21 illustrates a method for manufacturing a system for generating electricity from solar energy, in accordance with another embodiment of the present invention.

### DETAILED DESCRIPTION

As used in the specification and claims, the singular forms “a”, “an” and “the” include plural references unless the context clearly dictates otherwise. For example, the term “a photovoltaic module” may include a plurality of photovoltaic modules unless the context clearly dictates otherwise. A term having “-containing” such as “metal-containing” contains a metal but is open to other substances, but need not contain any other substance other than a metal.

Embodiments of the present invention provide an electronic substrate for use in a photovoltaic module and a method of fabricating the electronic substrate, a method and system for manufacturing a photovoltaic module, a system and apparatus for generating electricity from solar energy, and a method of fabricating the system for generating electricity from solar energy. In the description herein for embodiments of the present invention, numerous specific details are provided, such as examples of components and/or mechanisms, to provide a thorough understanding of embodiments of the present invention. One skilled in the relevant art will recognize, however, that an embodiment of the present invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

### Glossary

Integrated manner: In terms of the apparatus (photovoltaic module), it means that the electrically connected photovoltaic regions and the concentrator elements form an integrated and functional unit only at the module level. Any sub-part of the apparatus is not a functionally independent unit. In terms of the method of manufacturing in an integrated manner, it means that the assembly of the apparatus (photovoltaic module) consisting of photovoltaic regions, optical vees, and transparent member on the base substrate is carried out in one integrated sequence of operations without making functionally separate sub-units or sub-assemblies.
Photovoltaic module: A photovoltaic module is a packaged interconnected assembly of photovoltaic strips, which converts solar energy into electricity by the photovoltaic effect.
Electronic substrate: A substrate that provides mechanical support and electrical connectivity of components placed over it.
Base: A base is a term used to describe the base member of the electronic substrate.
Photovoltaic strip: A photovoltaic strip is a part of semiconductor wafer used in the fabrication of photovoltaic module.
Conductive pad: A conductive pad is a conductive strip formed over the electronic substrate. The photovoltaic strips are arranged over the conductive pads.
Path option: A path option is a metallic arrangement embedded in the base. The path option acts as an embedded wire connecting two photovoltaic strips.
Bond pad: A bond pad is a pad, made of a conductive material, formed over the base of the electronic substrate. The bond pad provides an interface to connect photovoltaic strips to path options.
Connectors: A connector is a thin wire made of a conducting material for electrically connecting two points.
Optical vee: An optical vee is a member with at least two surfaces arranged in the shape of ‘inverted-V’. Optionally, the optical vee includes a support element and a concentrating element overlying the support element.
Polymeric material: A polymeric material is a substance composed of molecules with large molecular mass composed of repeating structural units, or monomers, connected by covalent chemical bonds.
Concentrating element: A concentrating element is an optical member that acts as a medium for concentrating sunlight.
Pad space: Pad space is the area between the adjacent conductive pads.
Cavity: Cavity is three-dimensional region formed between adjacent optical vees and the photovoltaic strip that is placed between the adjacent optical vees.
Medium boundary: Medium boundary is a boundary between two mediums. For example, a medium boundary is formed at a boundary between glass and air.
Optically coupled: Optically coupled means a connection of two media of different/same refractive index so that there is no loss of light at the medium boundary.
Transparent member: Transparent member is an optically clear member placed over the photovoltaic module to seal and protect the photovoltaic module from environmental damage.
Anti-reflective coating: Anti-reflective coating is a coating over the transparent member to reduce loss of solar energy incident on the photovoltaic module.
Reflection-enhancing layer or surface: Reflection-enhancing layer or surface is a layer or surface that enhances the reflectivity of a surface.
Dicer: A dicer is for dicing a semiconductor wafer to form the photovoltaic strips.
Strip-arranger: A strip arranger is for arranging the photovoltaic strips over a base substrate.
Optical-vee placer: An optical-vee placer is for placing the optical vees in the spaces between the photovoltaic strips.
Concentrator placer: A concentrator placer places one or more pre-molded concentrating elements over pad spaces.
Dispenser: A dispenser is for dispensing the polymeric material in a fluid state over the cavities to form the molded concentrating elements.
Heater: A heater is for heating the photovoltaic module. For example, the photovoltaic module may be heated using a laminator.
Moulder: A moulder is for molding the polymeric material to form the optical vee.
Depositor: A depositor is for depositing the reflective material over the optical vees to form the reflective layer or surface.
Tool: A tool is for machining solid blocks of the reflective material to form the optical vee.
Polisher: A polisher is for polishing surface of the reflective layer or surface.
Bending Unit: A bending unit is for bending sheet/foil to form the optical vee.
Sandwiching Unit: A sandwiching unit is for sandwiching a foil of the reflective material between two plastic sheets to form a sandwiched foil.
Positioning unit: A positioning unit is for positioning the transparent member over the optical vees.
Power-consuming unit: A power-consuming unit is for consuming and/or storing the power generated by the photovoltaic module.
Sealing unit: A sealing unit is for sealing the transparent member with the base substrate.
AC Load: AC Load is a device that operates on Alternating Current (AC).
DC Load: DC Load is a device that operates on Direct Current (DC).
Charge controller: A charge controller controls the amount of charge consumed by the power-consuming unit.
Inverter: An inverter converts the electricity from a first form to a second form. For example, it converts electricity from AC to DC and vice-versa.

Embodiments of the photovoltaic module include a base substrate (also referred as backpanel), for example, made of anodized aluminum for providing a support to the photovoltaic module. Photovoltaic cell strips are arranged over the base substrate in strings with series and/or parallel arrangement, such that electrical output is maximized. The photovoltaic strips are arranged with spaces in between adjacent photovoltaic strips. A plurality of transparent and hollow optical vees are placed in the spaces between the photovoltaic strips and bonded to the aluminum backpanel. A plurality of trapezoidal shaped cavities is formed between adjacent optical vees. The trapezoidal shaped cavities have air/vacuum enclosed within them. The support element of the optical vees provides structural support and shape for a molded polymeric material (EVA) coating. The support element of the optical vees could be any vee-shaped support for the molded EVA coating, which could be made in the following manner.

An optically clear liquid polymeric material (EVA) of refractive index 1.5 could be made to flow over the support element of the optical vees and inside the trapezoidal cavities between the support element of the optical vees to form a molten molded EVA coating. An optically clear, low iron content glass cover sheet could be placed on the optical vees while the molded EVA coating is still in a molten form. The molten EVA coating is cured and solidified, thereby bonding the glass sheet to the optical vees, thereby forming an embodiment of the photovoltaic module.

When light falls on the module, it is total internally reflected at the polymeric material (EVA)-air interface and gets concentrated according to the geometric concentration ratio defined by the entry and exit aperture of the molded polymeric material (EVA). In the photovoltaic module, the cover glass and the aluminum backpanel are generally not sealed at the edges. Instead, the molded EVA coating over the optical vees seals the optical vees and the photovoltaic strips from moisture.

Embodiments of the photovoltaic module include a base substrate (also referred as backpanel), for example, made of anodized aluminum for providing a support to the photovoltaic module. Photovoltaic cell strips are arranged over the base substrate in strings with series and/or parallel arrangement, such that electrical output is maximized. The photovoltaic strips are arranged with spaces in between adjacent photovoltaic strips. A plurality of reflecting optical vees are placed in the spaces between the photovoltaic strips and bonded to the aluminum backpanel. The optical vees can be solid (like a glass prism) or hollow inside (like two mirrors forming a vee) with a reflective metal coating on the inside walls of the hollow optical vees. A plurality of trapezoidal shaped cavities is formed between adjacent optical vees. The trapezoidal shaped cavities have air/vacuum enclosed within them. An optically clear, low iron content glass cover sheet is generally placed on the optical vees. The cover glass and the aluminum backpanel are sealed at their edges using silicon to form an enclosed photovoltaic module that seals the inside of the module from moisture. When light falls on the module, it enters the cover glass and is total internally reflected at a reflecting surface of the optical vee (which could be a surface of a solid glass vee prism or a mirror-like inside surface of a hollow glass vee) and gets concentrated according to the geometric concentration ratio defined by the entry and exit aperture of the trapezoidal cavity.

The photovoltaic module includes an electronic substrate for providing mechanical support and electrical connections to the photovoltaic module. The electronic substrate includes a base for providing a plurality of path options, one or more bond pads, and one or more conductive pads formed over the base. The forming may, for example, be performed using the process of electroplating. Each conductive pad is electrically connected to at least one of the path options. The conductive pads may be of various shapes and sizes. For example, the conductive pads may be rectangular in shape, and may be arranged parallel to each other with pad spaces in between two adjacent conductive pads. One or more photovoltaic strips are arranged over the conductive pads. The photovoltaic strips may be rectangular in shape. The photovoltaic strips may also be square, triangular, or any other shape, in accordance with a desired configuration. The photovoltaic strips may be formed by dicing a semiconductor wafer. The bond pads provide an interface for connecting the photovoltaic strips to the path options in a predefined manner. The predefined manner may, for example, be a series and/or parallel arrangement, such that electrical output is maximized. The photovoltaic strips are connected to the bond pads through one or more connectors

One or more optical vees are placed over the pad spaces between the conductive pads, such that a plurality of cavities is formed between adjacent optical vees. For example, the optical vees may be placed in a manner, such that each photovoltaic strip has two adjacent optical vees. The optical vees may be hollow or solid. In an embodiment of the present invention, the cavities form a trapezoidal shape in cross-section. The optical vees are capable of concentrating solar energy over the photovoltaic strips. In an embodiment of the present invention, the optical vees have a reflective layer or surface, such that sun rays incident on the reflective layer or surface are reflected towards the photovoltaic strips. When the reflected sun rays fall on the photovoltaic strips, electricity is generated by the photoelectric effect.

In another embodiment of the present invention, the optical vees include a first medium and a second medium underlying the first medium. The ratio of the refractive index of the first medium to the refractive index of the second medium is greater than one. Examples of the first medium include, but are not limited to, plastics, glass, acrylics, and transparent polymeric materials. Examples of the second medium include, but are not limited to, air and vacuum. Total internal reflection occurs at a medium boundary between the first medium and the second medium. One or more concentrating elements are filled in the cavities. These concentrating elements may, for example, be formed by pouring a polymeric material in a fluid state over the cavities. The concentrating elements then take the shape of the cavities in cross-section. In another example, the concentrating elements are formed by re-molding pre-molded concentrating elements made of the polymeric material over the cavities. In yet another example, the concentrating elements made of the polymeric material may be in a pre-molded form. The polymeric material can be any material that is tolerant to moisture, Ultra Violet (UV) radiation, abrasion, and natural temperature variations. The refractive index of the polymeric material may, for example, be 1.5 or above. Examples of the polymeric material include, but are not limited to, Ethyl Vinyl Acetate (EVA), silicone, Thermoplastic Poly-Urethane (TPU), Poly Vinyl Butyral (PVB), acrylics, polycarbonates, and synthetic resins.

In an embodiment of the present invention, the photovoltaic module also includes a transparent member positioned over the optical vees. The transparent member is coated with an anti-reflective coating to reduce loss of solar energy incident on the photovoltaic module, in accordance with an embodiment of the present invention. In accordance with an embodiment of the present invention, the transparent member is sealed with the electronic substrate, and the electronic substrate, the photovoltaic strips, the optical vees and the transparent member form the photovoltaic module in an integrated manner.

The acceptance angle of the photovoltaic module is chosen, such that rays normally incident on the optical vees may be reflected and/or total internally reflected towards the photovoltaic strips with minimal optical losses. Tracking mechanisms may be used to change the position of the photovoltaic module, in order to keep the rays normally incident upon the photovoltaic module while the sun moves across the sky. This further enhances the power output of the photovoltaic module.

The photovoltaic module can be used in various applications. For example, an array of photovoltaic modules may be used to generate electricity on a large scale for grid power supply. In another example, photovoltaic modules may be used to generate electricity on a small scale for home/office use. Alternatively, photovoltaic modules may be used to generate electricity for stand-alone electrical devices, such as automobiles and spacecraft. Details of these applications have been provided in conjunction with drawings below.

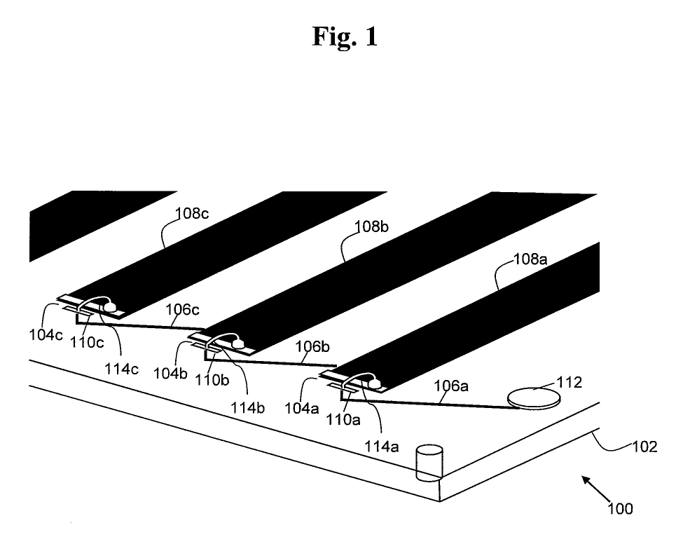

FIG. 1 illustrates an electronic substrate 100, in accordance with an embodiment of the present invention. Electronic substrate 100 includes a base 102, one or more conductive pads 104, a plurality of path options 106, one or more bond pads 110, a negative contact terminal 112, and one or more connectors 114. One or more photovoltaic strips 108 are arranged over conductive pads 104. In FIG. 1, conductive pads 104 are shown as a conductive pad 104a, a conductive pad 104b, and a conductive pad 104c. Path options 106 are shown as a path option 106a, a path option 106b, and a path option 106c. Photovoltaic strips 108 are shown as a photovoltaic strip 108a, a photovoltaic strip 108b, and a photovoltaic strip 108c. Bond pads 110 are shown as a bond pad 110a, a bond pad 110b, and a bond pad 110c. Connectors 114 are shown as a connector 114a, a connector 114b, and a connector 114c.

Electronic substrate 100 is suitable for use in a photovoltaic module. The photovoltaic module generates electricity from solar energy by the photoelectric effect. Base 102 provides electrical connectivity to various components placed over it. Base 102 may, for example, include conducting layers placed on a non-conducting material. Examples of such non-conducting materials include, but are not limited to, phenolic paper, glass fiber, ceramic and plastics. The non-conducting material can also be replaced by a pre-impregnated material. Examples of such pre-impregnated materials include, but are not limited to, a combination of glass fiber mat, nonwoven material and resin. Base 102 can be made of any material that is tolerant to moisture, Ultra Violet (UV) radiation, abrasion, and natural temperature variations. Examples of such materials include, but not limited to, aluminium, steel, plastics and suitable polycarbonates. In addition, base 102 may, for example, be made of plastics with metal coating or plastics with high thermal conductivity fillers. Examples of such fillers include, but are not limited to, boron nitride (BN), aluminium oxide, (Al₂O₃), and metals. Examples of electronic substrate 100 include, but are not limited to, Printed Circuit Boards (PCBs) and hybrid microcircuits.

With reference to FIG. 1, conductive pads 104 form a conducting layer. Conductive pads 104 are formed over electronic substrate 100, such that pad spaces are created between adjacent conductive pads 104. Conductive pads 104 provide a conductive base for arranging photovoltaic strips 108, and facilitate electrical contact between components placed over base 102. With reference to FIG. 1, conductive pads 104 are rectangular in shape and are spaced parallel to each other. Conductive pad 104a, conductive pad 104b, and conductive pad 104c are rectangular in shape and arranged parallel to each other over base 102. It should be noted that conductive pads 104 may be of various shapes and sizes. For example, conductive pads may be circular or arc-like in shape, and may be formed in the form of concentric circles. The conductive pads may also be square, triangular, or any other shape, in accordance with a desired configuration.

Path options 106 are embedded within base 102. Path options 106 act as embedded wires. This avoids the use of external conductors and further prevents short circuiting of components placed over the electronic substrate. Hence, each of conductive pads 104 is electrically connected to at least one of path options 106. With reference to FIG. 1, conductive pad 104a is connected to negative contact terminal 112 of electronic substrate 100 through path option 106a.

In an embodiment of the present invention, path options 106 are embedded in base 102 over which conductive pads 104 are formed. In another embodiment of the present invention, conductive pads 104 are formed over base 102, thereafter, path options 106 are embedded within base 102. In yet another embodiment of the present invention, the process of embedding and forming can be carried out simultaneously. In an embodiment of the present invention, electronic substrate 100 is a PCB. The processes of forming conductive pads and embedding involve various processes, such as electroplating, etching, silk screen printing, photoengraving, or PCB milling. Conductive pads 104 are made of suitable conductive materials, such as copper.

Bond pads 110 are pads made of a conductive material formed over base 102. Bond pads 110 may, for example, be formed over base 102 through the process of electroplating. In another embodiment, bond pads 110 are pins made of conductive material. Examples of such conductive materials include, but are not limited to, copper, and copper alloys, such as brass or phosphor bronze, tellurium copper, beryllium copper, and beryllium nickel. Bond pads 110 may be further plated with copper, lead, gold, silver, tin, nickel, and palladium. With reference to FIG. 1, bond pads 110 are rectangular in shape. Alternatively, bond pads 110 can be made in different shapes, such as an H-shape, a C-shape, or other suitable shape.

Photovoltaic strips 108 are arranged over conductive pads 104. With reference to FIG. 1, photovoltaic strip 108a is arranged over conductive pad 104a, photovoltaic strip 108b is arranged over conductive pad 104b, and photovoltaic strip 108c is arranged over conductive pad 104c. Photovoltaic strips 108 can be arranged over conductive pads 104 using, for example, soldering, bonding, or adhesives.

Photovoltaic strips 108 are made of a semiconductor material. Examples of semiconductor material include, but are not limited to, monocrystalline silicon (c-Si), polycrystalline or multicrystalline silicon (poly-Si or mc-Si), ribbon silicon, cadmium telluride (CdTe), copper-indium diselenide (CuInSe₂), combinations of III-V and II-VI elements in the periodic table that have photovoltaic effect, copper indium/gallium diselenide (CIGS), gallium arsenide (GaAs), germanium (Ge), gallium indium phosphide (GaInP₂), organic semiconductors such as polymers and small-molecule compounds like polyphenylene vinylene, copper phthalocyanine and carbon fullerenes, amorphous silicon (a-Si or a-Si:H), protocrystalline silicon, and nanocrystalline silicon (nc-Si or nc-Si:H). When electromagnetic radiation falls over photovoltaic strips 108, electron-hole pairs are separated by some means before they recombine giving rise to a voltage. When a load is connected across the two electrodes, the generated voltage drives a current producing electrical energy.

Bond pads 110 provide an interface to connect photovoltaic strips 108 to path options 106 in a predefined manner. For example, bond pad 110a connects photovoltaic strip 108a to path option 106a. Bond pads 110 are connected with photovoltaic strips 108 through connectors 114. Connectors 114 may, for example, be wires made of a conductive material, such as copper. With reference to FIG. 1, connector 114a connects photovoltaic strip 108a with bond pad 110a, connector 114b connects photovoltaic strip 108b with bond pad 110b, and so on. The predefined manner may, for example, be a series and/or parallel arrangement, such that electrical output is maximized. In FIG. 1, photovoltaic strips 108 are connected in series. The p-side of photovoltaic strip 108a is connected to bond pad 110b through embedded path option 106b. Bond pad 110b is further connected to n-side of photovoltaic strip 108b through connector 114b. Hence, the n-side of photovoltaic strip 108a is connected to the p-side of photovoltaic strip 108b. Similarly, the p-side of photovoltaic strip 108b is connected to the n-side of photovoltaic strip 108c through path option 106c, bond pad 110c, and connector 114c, and so on.

Further, the pad spaces created between adjacent conductive pads 104 are provided for placing optical vees. These optical vees are capable of concentrating solar energy to photovoltaic strips 108.

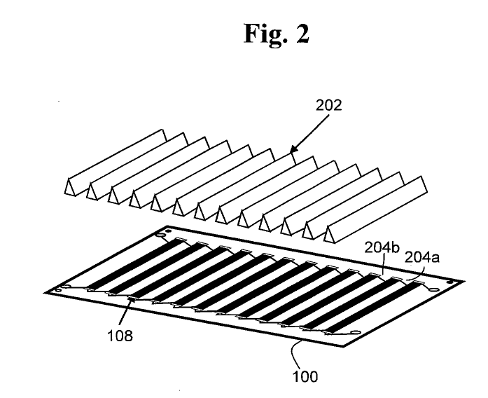

FIG. 2 illustrates how one or more optical vees 202 are placed over electronic substrate 100, in accordance with an embodiment of the present invention. As described in FIG. 1, electronic substrate 100 includes photovoltaic strips 108 arranged over conductive pads 104 (not shown in the figure). Conductive pads 104 are formed in a manner that one or more pad spaces 204 are created between adjacent conductive pads 104. Optical vees 202 are placed in pad spaces 204. With reference to FIG. 2, optical vee 202a is placed over a pad space 204a; optical vee 202b is placed over a pad space 204b, and so on. Electronic substrate 100 and optical vees 202 together form a photovoltaic module for generating electricity from solar energy.

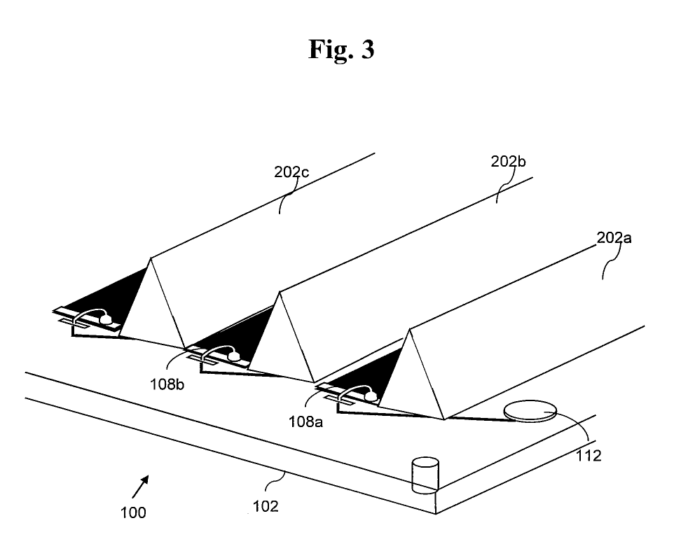

FIG. 3 illustrates a view of photovoltaic strips 108 and optical vees 202 placed over electronic substrate 100, in accordance with an embodiment of the present invention. With reference to FIG. 3, photovoltaic strip 108a and photovoltaic strip 108b are connected in series. Optical vee 202a, optical vee 202b, optical vee 202c are placed in between photovoltaic strips 108.

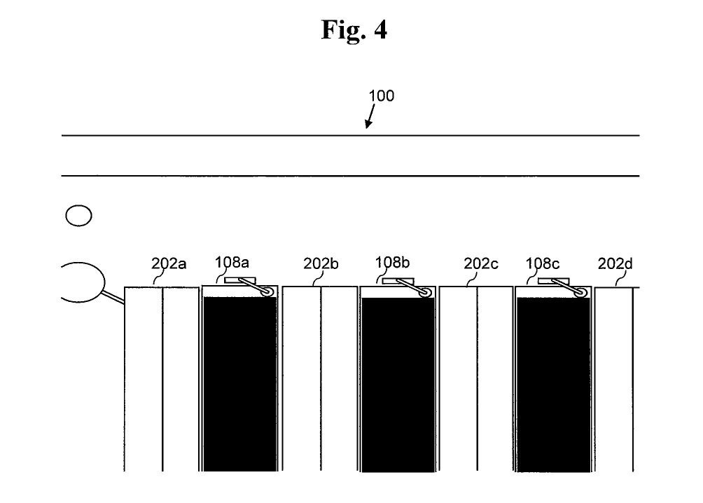

FIG. 4 illustrates a top view of electronic substrate 100, in accordance with an embodiment of the present invention. Optical vees 202 are placed in between photovoltaic strips 108, consecutively.

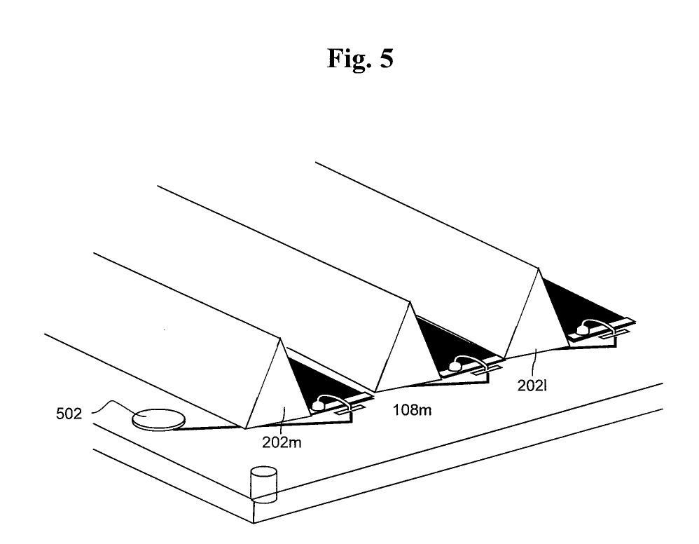

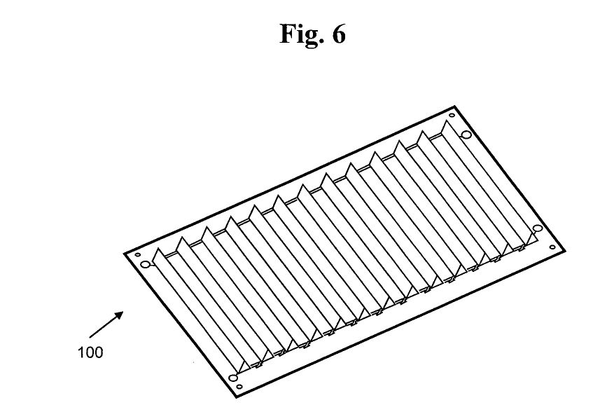

FIG. 5 illustrates another view of photovoltaic strips 108 and optical vees 202 placed over electronic substrate 100, in accordance with an embodiment of the present invention. An optical vee 2021 and an optical vee 202m are placed over pad spaces 204 (not shown in figure) on both sides of a photovoltaic strip 108m. Photovoltaic strip 108m is connected to positive contact terminal 502 of electronic substrate 100.

FIG. 6 shows a view of electronic substrate 100, in accordance with an embodiment of the present invention. Optical vees 202 are placed consecutively between photovoltaic strips 108. Electronic substrate 100, photovoltaic strips 108 and optical vees 202 form a photovoltaic module.

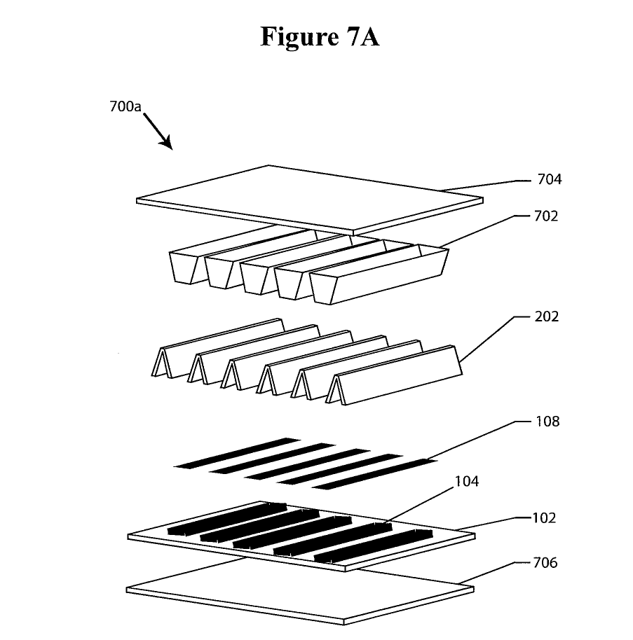

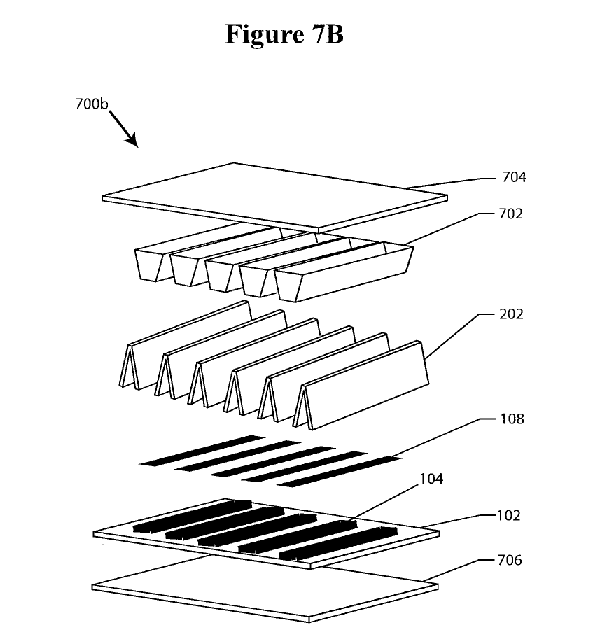

FIG. 7a illustrates a blown-up view of a photovoltaic module 700a, in accordance with an embodiment of the present invention. Photovoltaic module 700a includes electronic substrate 100 that includes base 102, conductive pads 104, and path options 106. Photovoltaic module 700a further includes photovoltaic strips 108, optical vees 202, one or more concentrating elements 702, a transparent member 704, and an aluminium frame 706.

As described earlier, electronic substrate 100 provides mechanical support and electrical connection to photovoltaic module 700a. Conductive pads 104 are electrically connected with path options 106. Photovoltaic strips 108 are arranged over conductive pads 104. Further, bond pads 110 are formed over base 102 to provide an interface for connecting photovoltaic strips 108 with path options 106. External connectors 114 connect the photovoltaic strips 108 to bond pads 110.

With reference to FIG. 7a, optical vees 202 are placed in the pad spaces between conductive pads 104 and at the outermost sides, such that a plurality of trapezoidal cavities are formed between optical vees 202. In an embodiment of the present invention, concentrating elements 702 are formed by pouring a polymeric material in a fluid state over the trapezoidal cavities, such that concentrating elements 702 takes the shape of the trapezoidal cavities. In another embodiment of the present invention, concentrating elements 702 are formed by re-molding pre-molded concentrating elements over the trapezoidal cavities. Space or air bubble is minimized between concentrating elements 702 and photovoltaic strips 108, and between concentrating elements 702 and optical vees 202. Concentrating elements 702 are optically coupled to photovoltaic strips 108. Concentrating elements 702 concentrate the electromagnetic radiation over photovoltaic strips 108. In yet another embodiment of the present invention, concentrating elements 702 are in a pre-molded form.

Concentrating elements 702 are made of a polymeric material. The polymeric material can be any material that is tolerant to moisture, Ultra Violet (UV) radiation, abrasion, and natural temperature variations. The refractive index of the polymeric material may, for example, be 1.5 or above. Examples of the polymeric material include, but are not limited to, Ethyl Vinyl Acetate (EVA), silicone, Thermoplastic Poly-Urethane (TPU), Poly Vinyl Butyral (PVB), acrylics, polycarbonates, and synthetic resins.

Transparent member 704 is sealed with concentrating elements 702, in accordance with an embodiment of the present invention. With reference to FIG. 7b, transparent member 704 is flat rectangular in shape. Transparent member 704 may have any desired shape, such as a curved shape.

Transparent member 704 protects photovoltaic strips 108, optical vees 202 and concentrating elements 702 from environmental damage, while allowing electromagnetic radiation falling on its surface to pass to concentrating elements 702. The refractive index of transparent member 704 can be varied, and the reflectivity of transparent member 704 can be minimized, to increase the efficiency of concentration. For example, transparent member 704 may be coated with an anti-reflective coating on its top and bottom surfaces, to reduce loss of solar energy incident on photovoltaic module 700a. Therefore, no reflection occurs at a medium boundary between air and transparent member 704. In addition, no refraction occurs at a medium boundary between transparent member 704 and concentrating elements 702 when the refractive index of transparent member 704 is equal to the refractive index of concentrating elements 702. Therefore, transparent member 704 is optically coupled with concentrating elements 702. Rays, incident on the medium boundary between transparent member 704 and concentrating elements 702, refract with an angle of refraction smaller than an angle of incidence, when the refractive index of transparent member 704 is less than the refractive index of concentrating elements 702. The shape of transparent member may, for example, be flat or curved.

As the seal at the edge of photovoltaic module 700a so formed may remain non-hermetic, an additional step of framing photovoltaic module 700a may be performed. This can be accomplished by mechanically attaching a frame 706 to photovoltaic module 700a. Frame 706 may be made of a metal or a metallic alloy. Aluminum may be used for this purpose, as it is cheaper and lighter than other metals and metallic alloys.

FIG. 7b illustrates a blown-up view of a photovoltaic module 700b, in accordance with another embodiment of the present invention. Photovoltaic module 700b includes electronic substrate 100, photovoltaic strips 108, optical vees 202, transparent member 704, and aluminium frame 706.

Electronic substrate 100 provides mechanical support and electrical connection to photovoltaic module 700b.

Base 102, conductive pads 104, path options 106, and bond pads 110, together form electronic substrate 100. Photovoltaic strips 108 are arranged over conductive pads 102.

With reference to FIG. 7b, optical vees 202 are placed over the pad spaces between conductive pads 104 and at the outermost sides. Optical vees 202 are inverted-V-shaped in cross-section, in accordance with an embodiment of the present invention. In accordance with another embodiment of the present invention, optical vees 202 are compound-parabolic-shaped in cross-section. Optical vees 202 have a reflective layer or surface, such that sun rays incident on the reflective layer or surface are reflected towards photovoltaic strips 108. Electron-hole pairs are formed when the reflected sun rays fall on photovoltaic strips 108 by the photoelectric effect. These electron-hole pairs are responsible for generation of electricity. Optical vees 202 may, for example, be made of glass, plastics, polymeric materials, Ethyl Vinyl Acetate (EVA), Thermoplastic Poly-Urethane (TPU), Poly Vinyl Butyral (PVB), silicone, acrylics, polycarbonates, metals, metallic alloys, metal compounds, and ceramics.

In an embodiment of the present invention, optical vees 202 are formed by machining solid blocks of a reflective material in a desired shape, and polishing the solid blocks to form the reflective layer or surface. In this case, optical vees 202 are solid.

In another embodiment of the present invention, optical vees 202 are formed by polishing a sheet of a reflective material, which may be bent in a desired shape of optical vees 202. In such a case, optical vees 202 are hollow, and optical vees 202 may, for example, be V-shaped or triangular in cross-section.

In yet another embodiment of the present invention, optical vees 202 are made of a foil of a reflective material sandwiched between two moldable sheets. The sheet can be made of a transparent member, for example, plastic. The sandwiched foil is bent in a desired shape of optical vees 202.

In still another embodiment of the present invention, optical vees 202 are formed by molding a polymeric material, and the reflective layer or surface is formed by coating optical vees 202 with a reflective material.

The reflective material may, for example, be a metal, a metallic alloy, or a metal compound. In accordance with an embodiment of the present invention, optical vees 202 include a reflection-enhancing layer or surface to enhance the reflectivity of optical vees 202.

Transparent member 704 is positioned over optical vees 202. Transparent member 704 is sealed with electronic substrate 100. Transparent member 704 protects optical vees 202 and photovoltaic strips 108 from environmental damage, while allowing electromagnetic radiation falling on its surface to pass through. Electronic substrate 100, photovoltaic strips 108, optical vees 202 and transparent member 704 form photovoltaic module 700b in an integrated manner. With reference to FIG. 7b, transparent member 704 is flat rectangular in shape. Transparent member 704 may have any desired shape, such as a curved shape.

The refractive index of transparent member 704 can be varied, while minimizing the reflectivity of transparent member 704, to increase the efficiency of concentration. Transparent member 704 is coated with an anti-reflective coating on its top and bottom surfaces, to reduce loss of solar energy incident on photovoltaic module 700b. Therefore, no reflection occurs at medium boundaries between air and transparent member 704.

As the seal at the edge of photovoltaic module 700b so formed may remain non-hermetic, an additional step of framing photovoltaic module 700b may be performed. This can be accomplished by mechanically attaching a frame 706 to photovoltaic module 700b. Frame 706 may be made of a metal or a metallic alloy. Aluminum may be used for this purpose, as it is cheaper and lighter than other metals and metallic alloys.

In an embodiment of the present invention, the fabrication of photovoltaic module 700a and photovoltaic module 700b is done by using a high-speed robotic assembly. The robotic assembly includes one or more robotic arms, which are employed for performing various processes during the fabrication. In one example, a robotic arm may be used to connect photovoltaic strips 108 to bond pads 110. In another example, the placement of optical vees 202 in between photovoltaic strips 108 may be done with another robotic arm. The processes of embedding, bonding and die attachment may also be performed with the robotic arms.

It is to be understood that the specific designation for photovoltaic module 700a, photovoltaic module 700b and their components is for the convenience of the reader and is not to be construed as limiting photovoltaic module 700a and photovoltaic module 700b and their components to a specific number, size, shape, type, material, or arrangement.

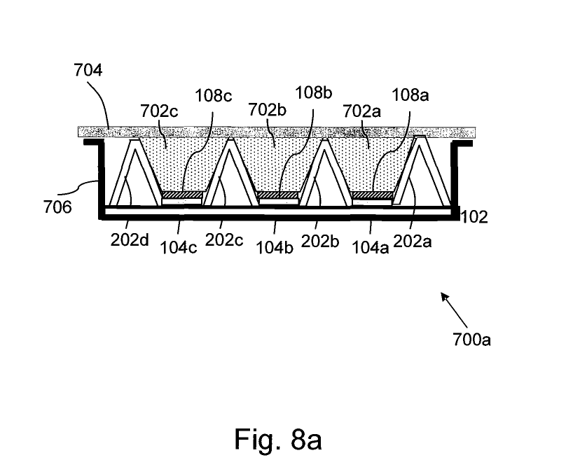

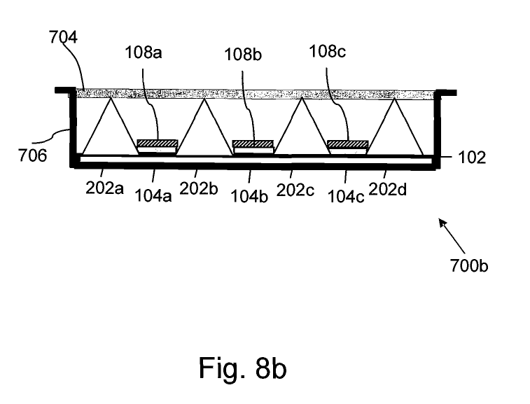

FIG. 8a illustrates a cross-sectional view of photovoltaic module 700a, in accordance with an embodiment of the present invention. In FIG. 8a, photovoltaic strips 108 are shown as photovoltaic strip 108a, photovoltaic strip 108b, and photovoltaic strip 108c. Optical vees 202 are shown as optical vee 202a, optical vee 202b, optical vee 202c, and an optical vee 202d. Concentrating elements 702 are shown as a concentrating element 702a, a concentrating element 702b, and a concentrating element 702c. With reference to FIG. 8a, concentrating element 702a is filled in a cavity between optical vee 202a and optical vee 202b; concentrating element 702b is filled in a cavity between optical vee 202b and optical vee 202c, and so on. As mentioned above, space or air bubble is minimized between concentrating elements 702 and photovoltaic strips 108, and between concentrating elements 702 and optical vees 202. Transparent member 704 with an anti-reflective coating is positioned over optical vees 202 and concentrating elements 702. Frame 706 may be mechanically attached to photovoltaic module 700a, and may, for example, be made of aluminium.

A single photovoltaic strip, a single optical vee and a single molded concentrating element are collectively termed as a ‘low concentrator unit’. A plurality of such low concentrator units may be combined together to form a photovoltaic module, in accordance with an embodiment of the present invention.

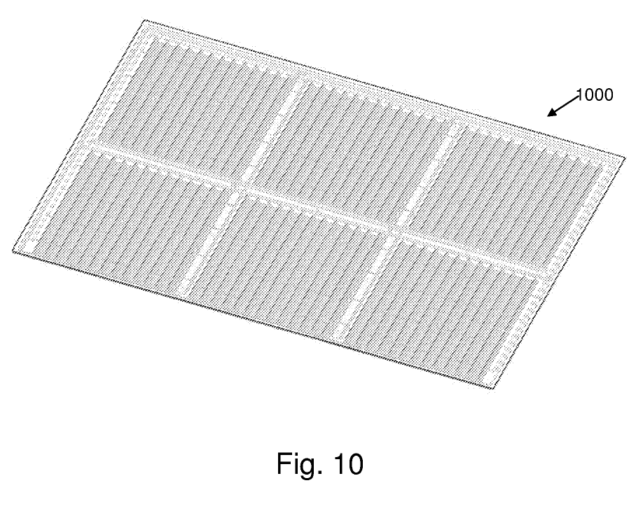

FIG. 8b illustrates a cross-sectional view of photovoltaic module 700b, in accordance with another embodiment of the present invention. In FIG. 8b, photovoltaic strips 108 are shown as a photovoltaic strip 108a, photovoltaic strip 108b, and photovoltaic strip 108c. Optical vees 202 are shown as an optical vee 202a, optical vee 202b, optical vee 202c, and an optical vee 202d. With reference to FIG. 10b, optical vee 202a and optical vee 202b concentrate solar energy towards photovoltaic strip 108a; optical vee 108b and optical vee 108c concentrate solar energy towards photovoltaic strip 108b, and so on. With reference to FIG. 8b, optical vees 202 are solid. Transparent member 704 with an anti-reflective coating is placed over optical vees 202.

A single photovoltaic strip and a single optical vee are collectively termed as a ‘low concentrator unit’. A plurality of such low concentrator units may be combined together to form a photovoltaic module, in accordance with another embodiment of the present invention.

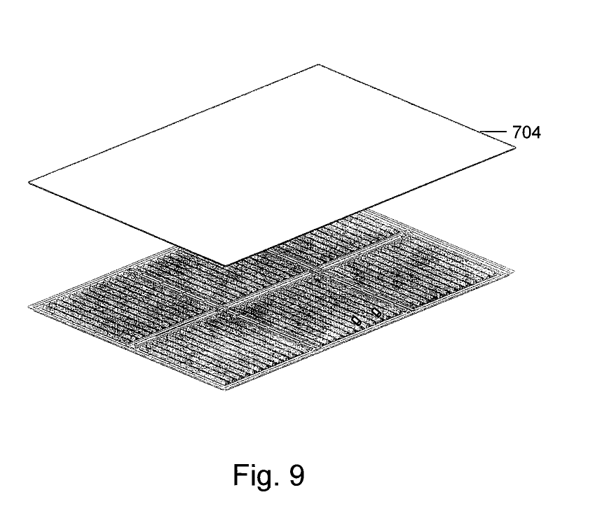

FIG. 9 is a perspective view illustrating a lay-up of a transparent member 704 over optical vees 202, in accordance with an embodiment of the present invention.

FIG. 10 is a perspective view of a photovoltaic module, in accordance with an embodiment of the present invention. The photovoltaic module may be either of photovoltaic module 700a and photovoltaic module 700b. It is to be understood that the specific designation for the photovoltaic module and its components as shown in FIGS. 1-9 is for the convenience of the reader and is not to be construed as limiting the photovoltaic module and its components to a specific number, size, shape, type, material, or arrangement.

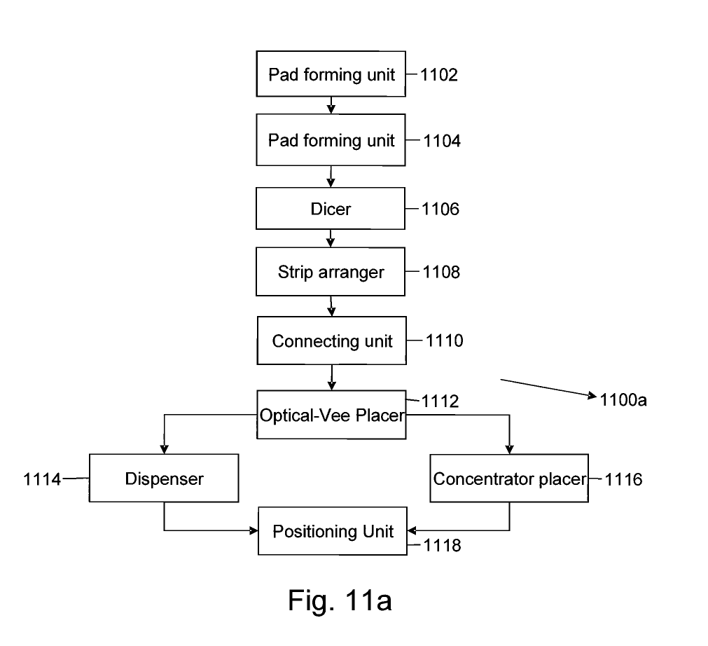

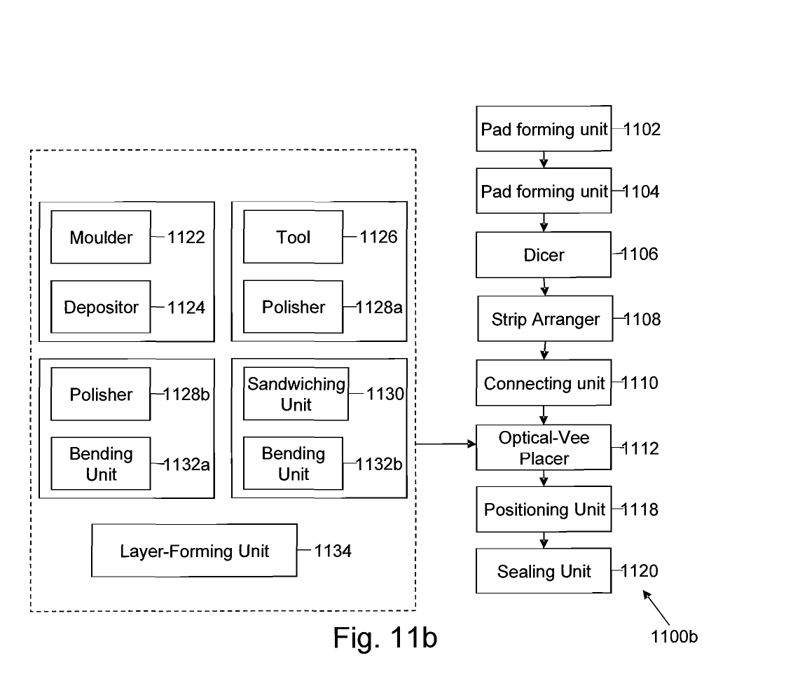

FIG. 11a illustrates a system 1100a for manufacturing photovoltaic module 700a, in accordance with an embodiment of the present invention. System 1100a includes a pad forming unit 1102, a pad forming unit 1104, a dicer 1106, a strip arranger 1108, a connecting unit 1110, an optical-vee placer 1112, a dispenser 1114, a concentrator placer 1116, and a positioning unit 1118.

In an embodiment, pad forming unit 1102 forms conductive pads 104 over base 102. Pad forming unit 1102, for example, may be an electroplating machine or for integrating conductive pads 104 to base 102.

Pad forming unit 1104 forms bond pads 110 over base 102. Pad forming unit 1104 may, for example, be an electroplating machine for integrating bond pads 110 to base 102.

In an embodiment, pad forming unit 1102 and pad forming unit 1104 can be integrated into a single unit.

In an embodiment of the present invention, dicer 1104 dices a semiconductor wafer to form a plurality of photovoltaic strips. Dicer 1106 may, for example, be a mechanical saw or a laser dicer. Laser dicers dice a semiconductor wafer from base side using a laser source. This provides a clean cut without any burrs, and involves minimal device damage.

Strip arranger 1108 arranges photovoltaic strips 108 over conductive pads 104. Strip arranger 1108 may, for example, be a pick-and-place unit that picks photovoltaic strips 108, and aligns and places over corresponding conductive pads 104.

In an embodiment, system 1100 further includes a die-bonder. The die-bonder bonds photovoltaic strips 108 to conductive pads 104. Die-bonder, for example, may be a soldering or a bonding machine.

Connecting unit 1110 connects photovoltaic strips 108 with bond pads 110 through connectors 114. Connecting unit 1110 may, for example, perform soldering using a manual process, a semi-automatic process, or a high-speed soldering machine. Solder-coated copper strips may, for example, be used as connectors 114. Conducting wires may be used as connectors 114.

Optical-vee placer 1112 places optical vees 202 over pad spaces 204 between conductive pads 104. Optical-vee placer 1112 may, for example, be a pick-and-place unit that picks optical vees 202, and aligns and places them.

In accordance with an embodiment of the present invention, dispenser 1114 dispenses a polymeric material in a fluid state over said cavities to form one or more molded concentrating elements, such that the molded concentrating elements take the shape of said cavities. The polymeric material can be any material that is tolerant to moisture, UV radiation, abrasion, and natural temperature variations. The refractive index of the polymeric material may, for example, be 1.5 or above. Examples of the polymeric material include, but are not limited to, EVA, silicone, TPU, PVB, acrylics, polycarbonates, and synthetic resins. Dispenser 1114 mixes the polymeric material with a hardener before pouring the polymeric material, in accordance with an embodiment of the present invention.

In accordance with another embodiment of the present invention, concentrator placer 1116 places one or more pre-molded concentrating elements over pad spaces 204. In accordance with yet another embodiment of the present invention, system 1100a also includes a heater for re-molding the pre-molded concentrating elements to form re-molded concentrating elements.

Positioning unit 1118 positions transparent member 704 over optical vees 202 and concentrating elements 702. Positioning unit 1118 may, for example, be a pick-and-place unit that picks transparent member 704, and aligns and places it as per the specified arrangement. Transparent member 704 is sealed to concentrating elements 702, in accordance with an embodiment of the present invention.

FIG. 11b illustrates a system 1100b for manufacturing photovoltaic module 700b, in accordance with another embodiment of the present invention. System 1100b includes pad forming unit 1102, pad forming unit 1104, dicer 1106, strip arranger 1108, connecting unit 1110, optical-vee placer 1112, positioning unit 1118, and a sealing unit 1120. System 1100b also includes a moulder 1122, a depositor 1124, a tool 1126, a polisher 1128a, a polisher 1128b, a sandwiching unit 1130, a bending unit 1132a, a bending unit 1132b, and a layer-forming unit 1134.

Pad forming unit 1102, pad forming unit 1104, dicer 1106, strip arranger 1108, connecting unit 1110, and positioning unit 1118 have been explained in FIG. 11a.

Optical-vee placer 1112 places optical vees 202 over pad spaces 204 between conductive pads 104. Optical-vee placer 1112 may, for example, be a pick-and-place unit that picks optical vees 202, and aligns and places them. The optical vees may be fabricated in different ways. In accordance with an embodiment of the present invention, moulder 1122 moulds a polymeric material to form the optical vees, and depositor 1124 deposits a reflective material over the optical vees to form a reflective layer or surface. Moulder 1122 may, for example, perform injection molding to mould optical vees of a desired shape. Optical vees may, for example, be inverted-V-shaped, and may be either hollow or solid. Depositor 1124 may, for example, perform a suitable Physical Vapour Deposition (PVD) process, such as a sputter deposition process.

In accordance with another embodiment of the present invention, tool 1126 machines solid blocks of a reflective material to form the optical vees, and polisher 1128a polishes surfaces of the machined solid blocks to form a reflective layer or surface. Tool 1126 may, for example, be a lathe machine.

In accordance with yet another embodiment of the present invention, polisher 1128b polishes a sheet of a reflective material to form a reflective layer or surface, and bending unit 1132a bends the sheet to form at least one of said optical vees. Bending unit 1132a may, for example, perform an automatic process of bending the sheet in a desired shape of optical vees. Polisher 1128a and polisher 1128b may either be parts of a polishing unit, or be the same unit.

In accordance with still another embodiment of the present invention, sandwiching unit 1130 sandwiches a foil of a reflective material between two sheets to form a sandwiched foil, and bending unit 1132b bends the sandwiched foil to form at least one of said optical vees. The sheets may, for example, be made of any material that is an electrical insulator and is suitable for bending. Examples of such material include, but are not limited to, polymeric materials, silicone, EVA, TPU, PVB, and plastics. The sheets may be optically transparent, as desired. Bending unit 1132b may, for example, perform an automatic process of bending the sandwiched foil in a desired shape of optical vees. Bending unit 1132a and bending unit 1132b may be the same unit.

Further, layer-forming unit 1134 forms a reflection-enhancing layer or surface over the optical vees to enhance the reflectivity of the optical vees, in accordance with an embodiment of the present invention.

With reference to FIG. 11b, positioning unit, 1118 positions transparent member 704 over optical vees 202. Positioning unit 1118 may, for example, be a pick-and-place unit that picks the transparent member, and aligns and places it as per the specified arrangement. Thereafter, sealing unit 1120 seals the transparent member with the base. In accordance with an embodiment of the present invention, the sealing is performed at the periphery. This may be accomplished by a resistive heating process using sealing rollers that melts a solder preform and forms a hermetic seal. Alternatively, the seal may be formed by a needle-dispensed epoxy, gasket sealing, glass frit, or EVA. In such a case, the seal so formed is non-hermetic, and an additional step of framing the photovoltaic module may be performed. This can be accomplished by mechanically attaching a frame to the photovoltaic module. The frame may be made of a metal or a metallic alloy. Aluminum may be used for this purpose, as it is cheaper and lighter than other metals and metallic alloys.

In accordance with an embodiment of the present invention, the base, the photovoltaic strips, the optical vees and the transparent member form the photovoltaic module in an integrated manner.

Various embodiments of the present invention provide an apparatus for generating electricity from solar energy. The apparatus includes supporting means for providing support to the apparatus, padding means for providing a conductive path, converting means for converting solar energy into electrical energy, interfacing means for providing an interface to connect the converting means, concentrating means for concentrating solar energy over the converting means, and connecting means for connecting the converting means to the interfacing means, The apparatus further includes transparent means positioned over the concentrating means. The padding means are arranged over the supporting means with pad spaces in between adjacent converting means. The converting means are placed over the padding means. The concentrating means are placed in the pad spaces between the padding means.

The supporting means may, for example, be electronic substrate 100. The padding means may, for example, be conductive pads 104. The converting means may, for example, be photovoltaic strips 108. The connecting means may, for example, be connectors 114. The concentrating means may, for example, be either optical vees 202 or optical vees 202 and concentrating elements 702. The transparent means may, for example, be transparent member 704.

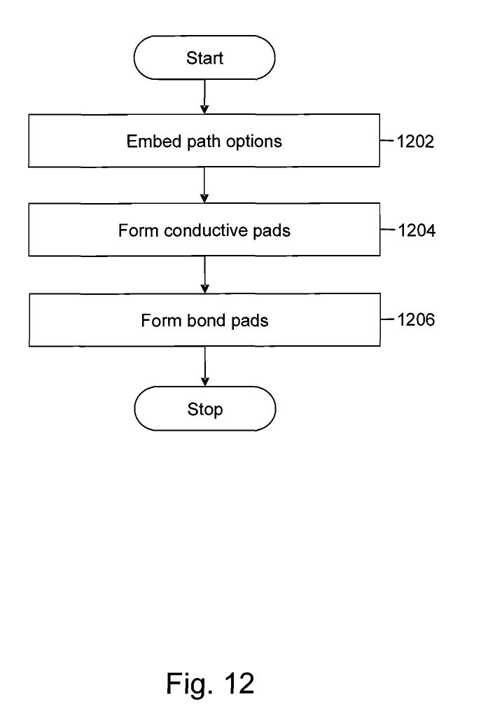

FIG. 12 is a flow diagram illustrating a method of fabricating an electronic substrate for use in a photovoltaic module, in accordance with an embodiment of the present invention. At step 1202, a plurality of path options are embedded in a base of the electronic substrate. At step 1204, one or more conductive pads are formed over the base, such that pad spaces are created between adjacent conductive pads. In an embodiment of the present invention, the electronic substrate is a Printed Circuit Board (PCB), and the processes of forming and embedding are accomplished by, for example, electroplating, etching, silk screen printing, photoengraving, or PCB milling. The conductive pads are further configured to receive one or more photovoltaic strips. At step 1206, one or more bond pads are formed over the base. The bond pads provide an interface to connect the photovoltaic strips to the path options in a predefined manner. The bond pads may, for example, be made of copper or copper alloys, such as brass or phosphor bronze, tellurium copper, beryllium copper, and beryllium nickel. The bond pads may be further plated with copper, lead, gold, silver, tin, nickel, and palladium. The predefined manner may, for example, be a series and/or parallel arrangement, such that electrical output is maximized.

Examples of the electronic substrate include, but are not limited to, a Printed Circuit Board (PCB), and a hybrid microcircuit.

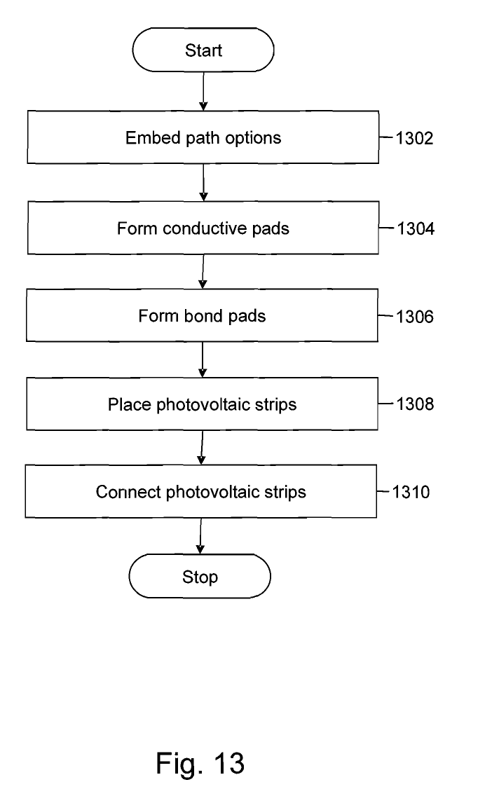

FIG. 13 is a flow diagram illustrating a method of fabricating an electronic substrate for use in a photovoltaic module, in accordance with another embodiment of the present invention. At step 1302, a plurality of path options are embedded in a base. At step 1304, one or more conductive pads are formed over the base, such that pad spaces are created between adjacent conductive pads. These pad spaces are configured to receive one or more optical vees. The conductive pads are electrically connected with at least one of the path options. The conductive pads are further configured to receive one or more photovoltaic strips.

At step 1306, one or more bond pads are formed over the base. At step 1308, the photovoltaic strips are arranged over the conductive pads. At step 1310, the photovoltaic strips are connected to bond pads through one or more connectors. This may be accomplished by manual soldering, wire bonding, and mesh bonding or by using a high-speed soldering machine, as explained in FIG. 1. Solder-coated copper strips may, for example, be used as the connectors. The photovoltaic strips are connected in a predefined manner. The predefined manner is a series and/or parallel arrangement, such that the electrical output is maximized.

The electronic substrate with connected photovoltaic strips, as mentioned above, can be used as a photovoltaic module for generating electricity from solar energy.

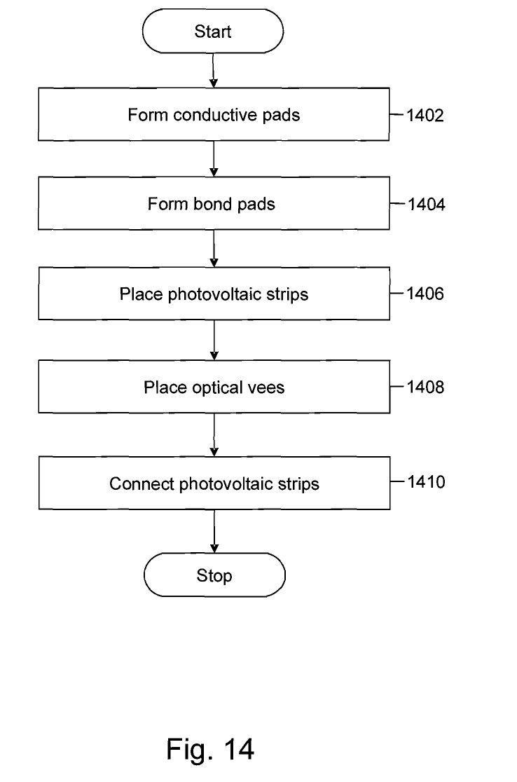

FIG. 14 is a flow diagram illustrating a method for manufacturing a photovoltaic module, in accordance with an embodiment of the present invention. At step 1402, one or more conductive pads are formed over a base of an electronic substrate. The base further has a plurality of path options that are embedded in the base. Examples of electronic substrate include, but are not limited to, a Printed Circuit Board (PCB), and a hybrid microcircuit. The conductive pads are configured to receive one or more photovoltaic strips. Conductive pads are formed over the electronic substrate in a manner, such that pad spaces are created between adjacent conductive pads.

At step 1404, one or more bond pads are formed over the base. The bond pads provide an interface to connect the photovoltaic strips to at least one of the plurality of path options in the predefined manner. At step 1406, one or more photovoltaic strips are arranged over the conductive pads. In one of the embodiments, the conductive pads are rectangular in shape and are placed parallel to each other. The photovoltaic strips are similar in shape to the conductive pads. Alternatively, both conductive pads and photovoltaic strips may be circular or arc-like in shape, and may be arranged in the form of concentric circles. The conductive pads and photovoltaic strips may also be square, triangular, or any other shape, in accordance with a desired configuration. Any combination of shapes and sizes of conductive pads and photovoltaic strips may be obtained.

At step 1408, a plurality of optical vees is placed in the spaces between the photovoltaic strips, such that a plurality of cavities is formed between adjacent optical vees. For example, the optical vees may be placed in a manner that each photovoltaic strip has two adjacent optical vees. The optical vees are capable of concentrating the solar energy to the photovoltaic strips.

At step 1410, the photovoltaic strips are connected to the bond pads through one or more connectors. In an embodiment, the p-side of the photovoltaic strips is connected to the bond pads with the help of an external connector. The bond pads are further connected to the n-side of the conductive pads through the path options. In this manner, a series connection of the photovoltaic strips is obtained.

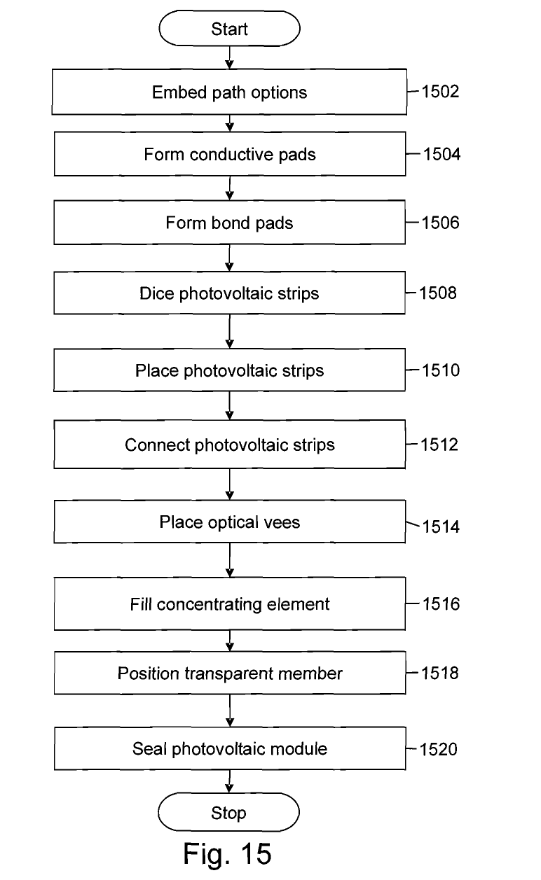

FIG. 15 is a flow diagram illustrating a method for manufacturing a photovoltaic module, in accordance with another embodiment of the present invention. At step 1502, a plurality of path options are embedded in a base of an electronic substrate. At step 1504, one or more conductive pads are formed over the base, such that pad spaces are created between adjacent conductive pads. Further, the conductive pads are electrically connected with the path options.

At step 1506, one or more bond pads are formed over the base. At step 1508, a semiconductor wafer is diced to form a plurality of photovoltaic strips. This can be accomplished by mechanical sawing or laser dicing. In laser dicing, a semiconductor wafer is diced from base side using a laser source. This provides a clean cut without any burrs, and involves minimal device damage. At step 1510, one or more photovoltaic strips are arranged over the conducting pads. At step 1512, the photovoltaic strips are connected to the bond pads through one or more connectors. This can be accomplished by manual soldering or soldering by using a high speed robotic assembly. In such a case, solder-coated copper strips may be used as the connectors. As mentioned above, the photovoltaic strips may be connected in series and/or parallel.

At step 1514, a plurality of optical vees is placed in the pad spaces between the photovoltaic strips, such that one or more cavities are formed between adjacent optical vees. As mentioned above, the optical vees may be placed in a manner that each photovoltaic strip has two adjacent optical vees. The optical vees include a first medium and a second medium underlying the first medium. The ratio of the refractive index of the first medium and the refractive index of the second medium is greater than one. Examples of the first medium include, but are not limited to, plastics, glass, acrylics, and transparent polymeric materials. Examples of the second medium include, but are not limited to, air and vacuum. Depending on the shape and configuration of the photovoltaic strips, optical vees with a suitable shape may be used. For example, rectangular optical vees may be used for rectangular photovoltaic strips. In accordance with an embodiment of the present invention, these optical vees form an inverted-V-shape in cross-section, and therefore, the cavities between these optical vees form a trapezoidal shape in cross-section.

At step 1516, the cavities are filled with concentrating elements. In an embodiment of the present invention, a polymeric material in a fluid state, such as a molten or a semi-molten state, is poured over the photovoltaic strips and the optical vees, such that the polymeric material fills the cavities between the optical vees. These cavities enable molding of the polymeric material, with minimum space or air bubble between the polymeric material and the photovoltaic strips, and between the polymeric material and the optical vees. The polymeric material may be further cured to form one or more concentrating elements. These concentrating elements concentrate solar energy over the photovoltaic strips. These concentrating elements take the shape of the cavities in cross-section. In accordance with an embodiment of the present invention, the concentrating elements form a trapezoidal shape in cross-section.

In another embodiment of the present invention, pre-molded concentrating elements are re-molded over the cavities. In yet another embodiment of the present invention, concentrating elements are placed over the cavities in a pre-molded form.

The concentrating elements are optically coupled to the photovoltaic strips. As mentioned above, space or air bubble is minimized between the concentrating elements and the optical vees, and between the concentrating elements and the photovoltaic strips. Therefore, optical defects are minimized. As mentioned above, the polymeric material can be any material that is tolerant to moisture, UV radiation, abrasion, and natural temperature variations.

At step 1518, a transparent member is positioned over the concentrating elements. The transparent member is optically coupled to the concentrating elements. The transparent member is optically transparent, and protects the concentrating elements and the photovoltaic strips from environmental damage, while allowing electromagnetic radiation falling on its surface to pass to the concentrating elements. It is desirable that the polymeric material has properties suitable for adhesion to glass. The refractive index of the polymeric material may, for example, be 1.5 or above. Examples of the polymeric material include, but are not limited to, EVA, silicone, TPU, PVB, acrylics, polycarbonates, and synthetic resins. The transparent member may, for example, be a toughened glass with low iron content, or be made of a polymeric material.

In order to increase the efficiency of concentration, various parameters, such as the reflectivity of the transparent member, and the refractive indices of the transparent member and the concentrating elements, may be manipulated. For example, the transparent member may be coated with an anti-reflective coating to reduce loss of solar energy incident on the photovoltaic module. In such a case, no reflection occurs at a medium boundary between air and the transparent member, thereby increasing the efficiency of concentration. In addition, no refraction occurs at a medium boundary between the transparent member and the concentrating elements when the refractive index of the transparent member is equal to the refractive index of the concentrating elements. In such a case, the medium boundary between the transparent member and the concentrating elements is optically transparent. Rays incident on the medium boundary refract with an angle of refraction smaller than an angle of incidence when the refractive index of the transparent member is less than the refractive index of the concentrating elements.

At step 1520, the photovoltaic strips are encapsulated with a second polymeric material to form a laminate. The process of lamination is performed at a prescribed temperature and/or pressure in a vacuum environment using a laminator. The vacuum environment ensures that minimum air bubbles are formed within the laminate. In order to avoid heat sinking during lamination, a supporting substrate can be used as a heat barrier, and removed later.

The second polymeric material can be any material that is tolerant to moisture, UV radiation, abrasion, and natural temperature variations. Examples of the second polymeric material include, but are not limited to, EVA, silicone, TPU, acrylic, polycarbonates, and synthetic resins, which can be laminated. In accordance with an embodiment of the present invention, the second polymeric material is the same as the polymeric material used at step 1514.

As the seal at the edge of the photovoltaic module so formed may remain non-hermetic, an additional step of framing the photovoltaic module may be performed. This can be accomplished by mechanically attaching an aluminum frame to the laminate.

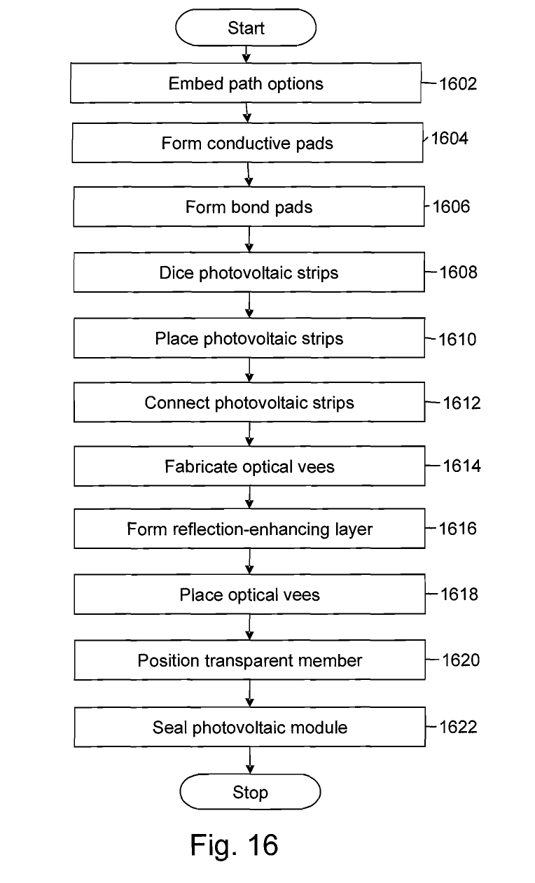

FIG. 16 is a flow diagram illustrating a method for manufacturing a photovoltaic module, in accordance with another embodiment of the present invention. At step 1602, a plurality of path options are embedded in a base of an electronic substrate. At step 1604, one or more conductive pads are formed over the base, such that pad spaces are created between adjacent conductive pads. Further, the conductive pads are electrically connected with at least one of the path options.

At step 1606, one or more bond pads are formed over the base. At step 1608, a semiconductor wafer is diced to form one or more photovoltaic strips. This can be accomplished by mechanical sawing or laser dicing. In laser dicing, a semiconductor wafer is diced from base side using a laser source. This provides a clean cut without any burrs, and involves minimal device damage.

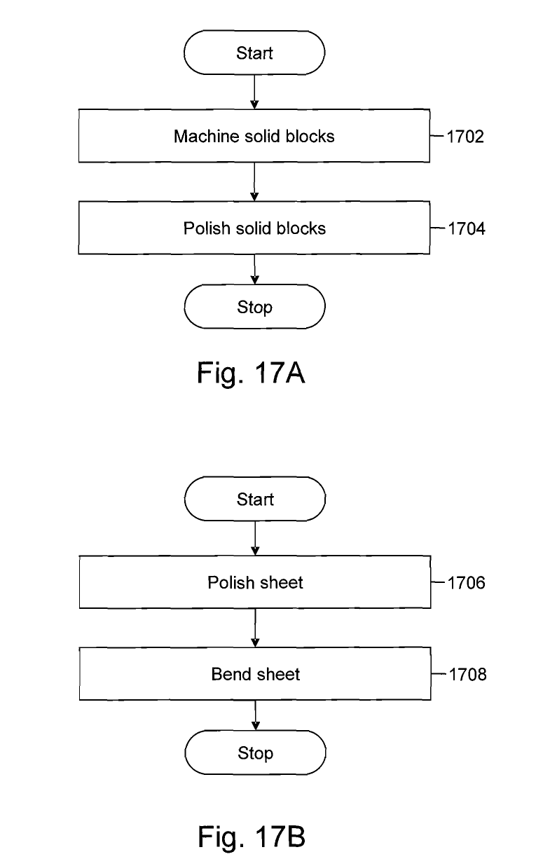

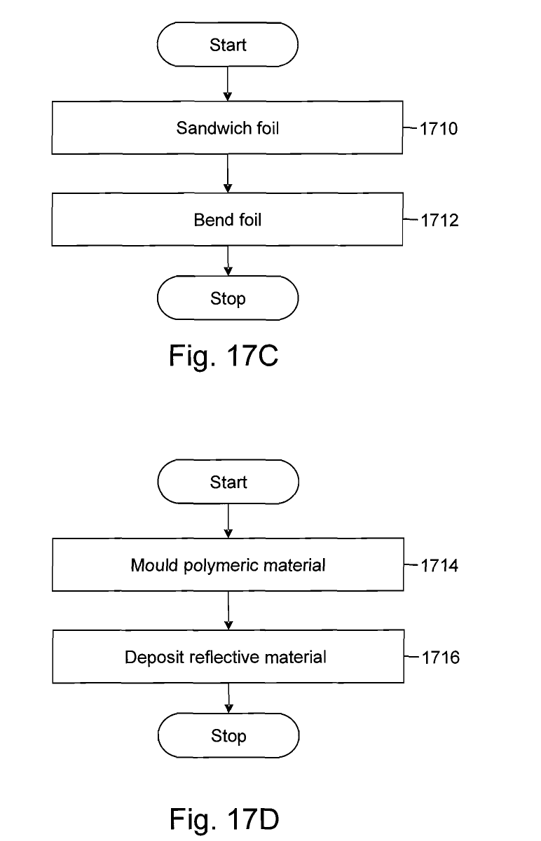

At step 1610, optical vees are fabricated. Optical vees may be fabricated in various ways. Details of the same have been provided in conjunction with FIG. 17A-D. At step 1612, a reflection-enhancing layer or surface is formed over the optical vees to enhance the reflectivity of the optical vees.

At step 1614, one or more photovoltaic strips are arranged over the conductive pads. At step 1616, the photovoltaic strips are connected with the bond pads through one or more connectors. This may be accomplished by manual soldering or by soldering using a high-speed soldering machine. Solder-coated copper strips may, for example, be used as the connectors. Alternatively, the connectors can be conductive wires. As mentioned above, the photovoltaic strips may be connected in series and/or parallel.

At step 1618, a plurality of optical vees is placed in the spaces between the photovoltaic strips, such that solar energy is concentrated over the optical vees. As mentioned above, the optical vees have a reflective layer or surface, and may be either hollow or solid. The optical vees may, for example, be made of glass, plastics, polymeric materials, EVA, TPU, PVB, silicone, acrylics, polycarbonates, metals, metallic alloys, metal compounds and ceramics.

At step 1620, a transparent member is coated with an anti-reflective coating to reduce loss of solar energy incident on the photovoltaic module. Therefore, no reflection occurs at medium boundaries between air and the transparent member. The anti-reflective coating may, for example, be made of silicon nitride, an oxide of silicon, or an oxide of titanium.

At step 1622, the photovoltaic strips and the optical vees are sealed with the transparent member. The transparent member is positioned over the optical vees. The transparent member protects the photovoltaic strips and the optical vees from environmental damage, while allowing electromagnetic radiation falling on its surface to pass through it. The transparent member may, for example, be made of glass, plastics, polymeric materials and EVA. The transparent member may, for example, be a toughened glass with low iron content, or be made of a suitable polymeric material which is non-UV-degradable.

In an embodiment of the present invention, the transparent member is sealed around the corners to the base, using a suitable material. This may be accomplished by a resistive heating process using sealing rollers that melts a solder preform and forms a hermetic seal. The seal may also be formed by a needle-dispensed epoxy, gasket sealing, glass frit, or EVA. As the seal at the edge of the photovoltaic module so formed may remain non-hermetic, an additional step of framing the photovoltaic module may be performed. This can be accomplished by mechanically attaching a frame to the photovoltaic module. The frame may be made of a metal or a metallic alloy. Aluminium may be used for this purpose, as it is cheaper and lighter than other metals and metallic alloys.

FIG. 17A-D illustrate various methods of fabricating optical vees. FIG. 17A illustrates a method of fabricating optical vees, in accordance with an embodiment of the present invention. At step 1702, solid blocks of a reflective material are machined to form the optical vees. At step 1704, surfaces of each solid block are polished to form a reflective layer or surface.

FIG. 17B illustrates a method of fabricating optical vees, in accordance with another embodiment of the present invention. At step 1706, a sheet of a reflective material is polished to form a reflective layer or surface. At step 1708, the polished sheet is bent to form at least one of the optical vees.

FIG. 17C illustrates a method of fabricating optical vees, in accordance with yet another embodiment of the present invention. At step 1710, a foil of a reflective material is sandwiched between two sheets to form a sandwiched foil. The sandwiched foil forms the reflective layer or surface. At step 1712, the sandwiched foil is bent to form at least one of the optical vees.

FIG. 17D illustrates a method of fabricating optical vees, in accordance with still another embodiment of the present invention. At step 1714, a polymeric material is molded to form the optical vees. At step 1716, a reflective material is deposited over the optical vees to form a reflective layer or surface.

The reflective material can be any metal, metallic alloy, or metal compound that is resistant to damage due to moisture and natural temperature variations, and has high reflectivity. Examples of such reflective material include, but are not limited to, aluminium, silver, nickel and steel. Aluminium may be used as a reflective material, as it is cheaper than other materials. However, in certain cases, silver may be used, as its reflectivity is sufficiently higher than aluminium to offset the difference in cost.

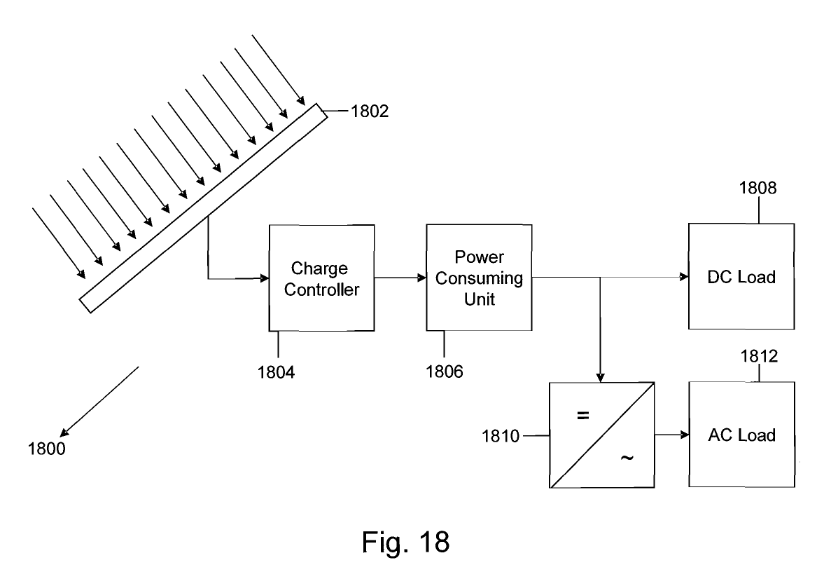

FIG. 18 illustrates a system 1800 for generating electricity from solar energy, in accordance with an embodiment of the present invention. System 1800 includes a photovoltaic module 1802, a charge controller 1804, a power-consuming unit 1806, a Direct Current (DC) load 1808, an inverter 1810 and an Alternating Current (AC) load 1812.

Photovoltaic module 1802 generates electricity from the solar energy that falls on photovoltaic module 1802. Photovoltaic module 1802 is similar to photovoltaic module 700a or photovoltaic module 700b. Power-consuming unit 1806 is connected with photovoltaic module 1802. Power-consuming unit 1806 consumes and/or stores the charge generated by photovoltaic module 1802. Power-consuming unit 1806 may, for example, be a battery.

In an embodiment of the present invention, charge controller 1804 is connected with photovoltaic module 1802 and power-consuming unit 1806. Charge controller 1804 controls the amount of charge consumed in power-consuming unit 1806. For example, if the amount of charge stored in power-consuming unit 1806 exceeds a first threshold, charge controller 1804 discontinues further charging of power-consuming unit 1806. Similarly, if the amount of charge stored in power-consuming unit 1806 falls below a second threshold, charge controller 1804 reinitiates charging of power-consuming unit 1806. In an embodiment of the present invention, the first threshold and the second threshold lie between the maximum and the minimum capacity of power-consuming unit 1806.

Power-consuming unit 1806 produces electricity in a first form. In an embodiment of the present invention, the first form is a DC that can be utilized by DC load 1808. DC load 1808 may, for example, be a device that operates on DC. In another embodiment of the present invention, the first form is an AC that can be utilized by AC load 1812. AC load 1812 may, for example, be a device that operates on AC.

Inverter 1810 is connected with power-consuming unit 1806. Inverter 1810 converts electricity from the first form to a second form, as required. The second form may be either DC or AC. Consider, for example, that the first form is DC, and a device requires electricity in the second form, that is, AC. Inverter 1810 converts DC into AC.

System 1800 may be implemented at a roof top of a building, for home or office use. Alternatively, system 1800 may be implemented for use with stand-alone electrical devices, such as automobiles and spacecraft.

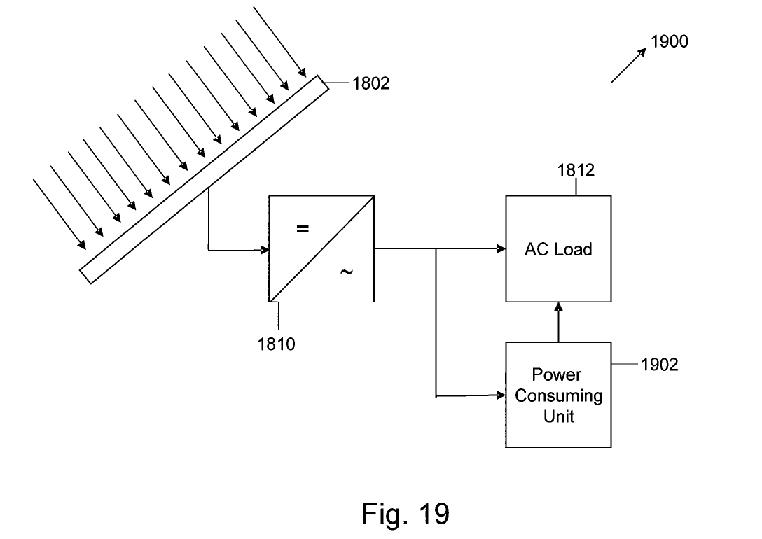

FIG. 19 illustrates a system 1900 for generating electricity from solar energy, in accordance with another embodiment of the present invention. System 1900 includes photovoltaic module 1802, inverter 1810, AC load 1812 and a power-consuming unit 1902.

As mentioned above, inverter 1810 converts electricity generated by photovoltaic module 1802 from the first form to the second form. With reference to FIG. 19, electricity in the second form is utilized by power-consuming unit 1902. Power-consuming unit 1902 may, for example, be a utility grid. For example, an array of photovoltaic modules 1902 may be used to generate electricity on a large scale for grid power supply.

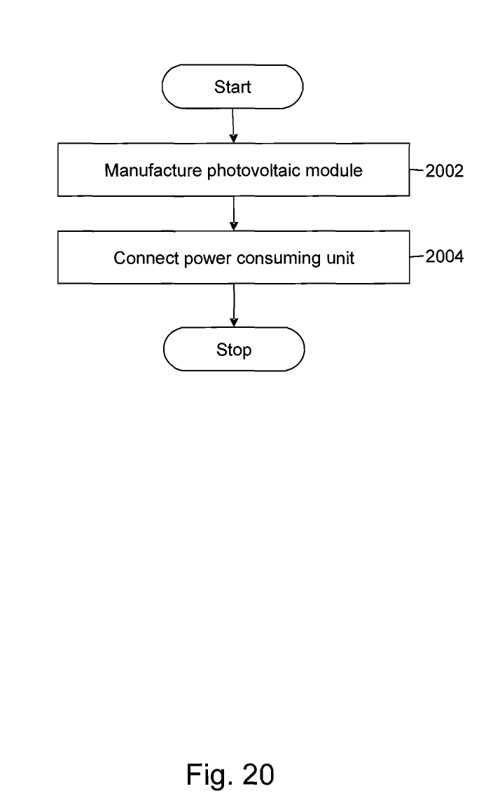

FIG. 20 illustrates a method for manufacturing a system for generating electricity from solar energy, in accordance with an embodiment of the present invention.

At step 2002, a photovoltaic module is manufactured as described in FIGS. 1, 7a, 7b, 14, 15, 16, 17A-D. The photovoltaic module may, for example, be photovoltaic module 700a or photovoltaic module 700b. At step 2004, a power-consuming unit is connected to the photovoltaic module. The power-consuming unit consumes the charge generated by the photovoltaic module. The power-consuming unit may either be a battery or a utility grid.

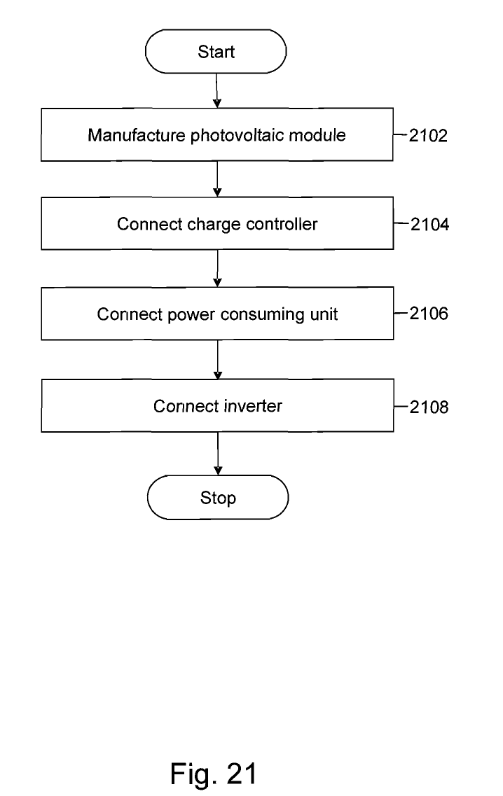

FIG. 21 illustrates a method for manufacturing a system for generating electricity from solar energy, in accordance with another embodiment of the present invention.

At step 2102, a photovoltaic module is manufactured as described in FIGS. 1, 7a, 7b, 14, 15, 16, 17A-D. The photovoltaic module may, for example, be photovoltaic module 700a or photovoltaic module 700b. At step 2104, a charge controller is connected with the photovoltaic module. At step 2106, a power-consuming unit is connected with the charge controller. As explained above, the charge controller controls the amount of charge stored in the power-consuming unit. For example, if the amount of charge stored in the power-consuming unit exceeds a first threshold, the charge controller discontinues further charging of the power-consuming unit. Similarly, if the amount of charge stored in the power-consuming unit falls below a second threshold, the charge controller reinitiates charging of the power-consuming unit. In an embodiment of the present invention, the first threshold and the second threshold lie between the maximum and the minimum capacity of the power-consuming unit.

The power-consuming unit provides the electricity in a first form. Devices that use the first form of electricity may directly be connected to the power-consuming unit. However, devices that use a second form of electricity require that the first form be converted to the second form. At step 2108, an inverter is connected with the power-consuming unit. The inverter converts the electricity from the first form to the second form. Examples of the first form and the second form include DC and AC.

Embodiments of the present invention provide an electronic substrate suitable for use in a photovoltaic module. The electronic substrate includes embedded path options. This avoids short circuiting with various components of the photovoltaic module. This, in turn, increases the life time of the photovoltaic module so formed.

In addition, the electronic substrate can be fabricated with completely automated processes and machines, thereby enabling mass manufacturing.

Further, the fabrication of the photovoltaic module involves the similar processes and machines that are required to fabricate conventional low concentrator photovoltaic modules. Therefore, the method of fabrication of the photovoltaic module is easy, quick and cost-effective.

Moreover, the photovoltaic module provides maximized outputs, at appropriate configurations of the photovoltaic strips and appropriate levels of concentration. Therefore, the photovoltaic module requires lesser amount of semiconductor material to generate same electrical output compared to conventional low concentrator photovoltaic modules.

This application may disclose several numerical range limitations that support any range within the disclosed numerical ranges even though a precise range limitation is not stated verbatim in the specification because the embodiments of the invention could be practiced throughout the disclosed numerical ranges. Finally, the entire disclosure of the patents and publications referred in this application, if any, are hereby incorporated herein in entirety by reference.

What is claimed is:

1. An electronic substrate for use in a photovoltaic module, said electronic substrate comprising:
a base for providing a plurality of path options;
one or more conductive pads formed over said base, such that pad spaces are created between adjacent conductive pads, said conductive pads configured to receive one or more photovoltaic strips, wherein said conductive pads are electrically connected with at least one of said path options; and
one or more bond pads formed over said base, wherein said bond pads provide an interface to connect said photovoltaic strips to said path options in a predefined manner.

2. The electronic substrate of claim 1 further comprising one or more connectors for connecting said photovoltaic strips to said bond pads.

3. The electronic substrate of claim 1, wherein said pad spaces are configured to receive one or more optical vees for concentrating solar energy over said photovoltaic strips.

4. The electronic substrate of claim 1, wherein said base is selected from the group consisting of a printed circuit board (PCB) and a hybrid microcircuit.

5. A photovoltaic module for generating electricity from solar energy, said photovoltaic module comprising:
an electronic substrate for providing support to said photovoltaic module, said electronic substrate comprising:
a base for providing a plurality of path options;
one or more conductive pads formed over said base, such that pad spaces are created between adjacent conductive pads, said conductive pads being electrically connected with at least one of said path options; and
one or more bond pads formed over said base;
one or more photovoltaic strips arranged over said conductive pads, said photovoltaic strips being capable of converting solar energy into electrical energy, wherein said bond pads provide an interface to connect said photovoltaic strips to said path options in a predefined manner;
one or more optical vees placed over said pad spaces, such that a plurality of cavities is formed between adjacent optical vees, wherein said optical vees are capable of concentrating solar energy over said photovoltaic strips; and
one or more connectors for connecting said photovoltaic strips to said bond pads.

6. The photovoltaic module of claim 5, wherein the predefined manner is a series and/or parallel arrangement.

7. The photovoltaic module of claim 5, wherein said optical vees comprise a reflective layer or surface, such that rays incident on said reflective layer or surface are reflected towards said photovoltaic strips.

8. The photovoltaic module of claim 5, wherein said optical vees comprise solid blocks of a reflective material.

9. The photovoltaic module of claim 5, wherein said optical vees further comprise:
a first medium;
a second medium, said second medium underlying said first medium such that a ratio of a refractive index of said first medium to a refractive index of said second medium is greater than one.

10. The photovoltaic module of claim 5 further comprising one or more concentrating elements, said concentrating elements being capable of concentrating solar energy over said photovoltaic strips.

11. The photovoltaic module of claim 10, wherein said concentrating element comprises a polymeric material that has the shape of said cavities.

12. The photovoltaic module of claim 10, wherein said concentrating element comprises re-molded concentrating elements.

13. The photovoltaic module of claim 10, wherein said concentrating element is a pre-molded concentrating element.

14. The photovoltaic module of claim 5 further comprising a transparent member positioned over said optical vees.

15. An apparatus for generating electricity from solar energy, said apparatus comprising:
supporting means for providing support to said apparatus, wherein said supporting means provides a plurality of path options;
padding means for providing a conductive path, said padding means formed over said supporting means, such that pad spaces are created between adjacent padding means, said padding means being electrically connected to at least one of said path options;
converting means for converting solar energy into electrical energy, said converting means being arranged over said padding means;
interfacing means for providing an interface to connect said converting means to said path options in a predefined manner, said interfacing means being formed over said supporting means;
concentrating means for concentrating solar energy over said converting means; and
connecting means for connecting said converting means to said interfacing means.

16. The apparatus of claim 15, wherein a plurality of said concentrating means is placed over said pad spaces, such that a plurality of cavities is formed between adjacent concentrating means.

17. The apparatus of claim 15 further comprising a transparent means for transmitting solar energy, the transparent means being positioned over said concentrating means.

18. A system for manufacturing a photovoltaic module, said system comprising:
a pad forming unit configured to:
form one or more conductive pads over an electronic substrate, wherein said electronic substrate provides a base comprising a plurality of path options, wherein said conductive pads are arranged, such that pad spaces are created between adjacent conductive pads, said conducting pads are electrically connected with at least one of said path options; and
form one or more bond pads over the base;
a strip-arranger for arranging one or more photovoltaic strips over said conductive pads, wherein said photovoltaic strips are capable of converting solar energy into electrical energy, wherein said bond pads provide an interface to connect said photovoltaic strips to said path options in a predefined manner;
an optical-vee-placer for placing a plurality of optical vees over said pad spaces, such that a plurality of cavities is formed between adjacent optical vees; and
a connecting unit for connecting said photovoltaic strips to said bond pads.

19. The system of claim 18 further comprising a dispenser for pouring a polymeric material in a fluid state over said cavities to form one or more molded concentrating elements, such that said molded concentrating elements take the shape of said cavities.

20. The system of claim 18 further comprising a dicer for dicing a semiconductor wafer to form said photovoltaic strips.

21. The system of claim 18 further comprising:
a moulder for molding a polymeric material to form at least a portion of said optical vees; and
a depositor for depositing a reflective material to form a reflective layer or surface.

22. The system of claim 18 further comprising:
a tool for machining solid blocks of a reflective material to form at least a portion of said optical vees; and
a polisher for polishing said solid blocks to form a reflective layer or surface.

23. The system of claim 18 further comprising:
a polisher for polishing a sheet of a reflective material to form a reflective layer or surface; and
a bending unit for bending said sheet to form at least a portion of one of said optical vees.

24. The system of claim 18 further comprising:
a sandwiching unit for sandwiching a foil of a reflective material between two sheets to form a sandwiched foil, said sandwiched foil forming a reflective layer or surface; and
a bending unit for bending said sandwiched foil to form at least a portion of one of said optical vees.

25. A system for generating electricity from solar energy, said system comprising:
a photovoltaic module comprising:
a base for providing support to said photovoltaic module, wherein said base provides a plurality of path options;
one or more conductive pads formed over said base, such that pad spaces are created between adjacent conductive pads, said conductive pads being electrically connected with at least one of said path options;
one or more bond pads formed over said base;
one or more photovoltaic strips arranged over said conductive pads, said photovoltaic strips being capable of converting solar energy into electrical energy, wherein said bond pads provide an interface to connect said photovoltaic strips to said path options in a predefined manner;
one or more optical vees placed over said pad spaces, such that a plurality of cavities is formed between adjacent optical vees, wherein said optical vees are capable of concentrating solar energy over said photovoltaic strips; and
one or more connectors for connecting said photovoltaic strips to said bond pads; and
a power-consuming unit for consuming charge generated by said photovoltaic module, said power-consuming unit being connected with said photovoltaic module.

26. The system of claim 25 further comprising a charge controller for controlling the amount of charge in said power-consuming unit, wherein said charge controller is connected with said power-consuming unit.

27. The system of claim 25 further comprising an inverter for converting electricity from a first form to a second form, wherein electricity is generated by flow of charge stored in said power-consuming unit, said inverter is connected with said power-consuming unit.

28. The system of claim 27, wherein said first form and said second form are selected from the group consisting of direct current and alternating current.

29. A method of manufacturing a photovoltaic module, the method comprising:
forming one or more conductive pads over an electronic substrate, such that pad spaces are created between adjacent conductive pads, wherein said electronic substrate provides a base with a plurality of path options, said conducting pads are electrically connected with at least one of said path options;
forming one or more bond pads over said base;
arranging one or more photovoltaic strips over said conductive pads, said photovoltaic strips capable of converting solar energy into electrical energy, wherein said bond pads provide an interface to connect said photovoltaic strips to said path options in a predefined manner;
placing a plurality of optical vees over said pad spaces, such that a plurality of cavities is formed between adjacent optical vees, said optical vees being capable of concentrating solar energy over said photovoltaic strips; and
connecting said photovoltaic strips to said bond pads.

30. The method of claim 29, wherein said optical vees comprise a reflective layer or surface, such that rays incident on said reflective layer or surface are reflected towards said photovoltaic strips.

31. The method of claim 30 further comprising:
molding a polymeric material to form said optical vees; and
depositing a reflective material to form said reflective layer or surface.

32. The method of claim 30 further comprising:
machining solid blocks of a reflective material to form said optical vees; and
polishing said solid blocks to form said reflective layer or surface.

33. The method of claim 30 further comprising:
polishing a sheet of a reflective material to form said reflective layer or surface; and
bending said sheet to form at least one of said optical vees.

34. The method of claim 30 further comprising:
sandwiching a foil of a reflective material between two sheets to form a sandwiched foil comprising said reflective layer or surface; and
bending said sandwiched foil to form at least one of said optical vees.

35. The method of claim 29, wherein said optical vees comprise:
a first medium; and
a second medium underlying said first medium, wherein the ratio of a refractive index of said first medium to a refractive index of said second medium is greater than one.

36. The method of claim 29 further comprising filling one or more concentrating elements in said cavities, said concentrating elements being capable of concentrating solar energy over said photovoltaic strips.

37. The method of claim 36, wherein said concentrating elements are in a pre-molded form.

38. The method of claim 36, wherein said filling said concentrating elements comprises re-molding pre-molded concentrating elements to form re-molded concentrating elements.

39. The method of claim 36, wherein said filling said concentrating elements comprises pouring a polymeric material in a fluid state over said photovoltaic strips in said cavities, such that molded concentrating elements take the shape of said cavities.

40. The method of claim 36, wherein a refractive index of said optical vees is equal to a refractive index of said concentrating elements, such that an interface between said support elements and said concentrating elements is substantially optically transparent.

41. The method of claim 29 further comprising positioning a transparent member over said optical vees.

42. A method of fabricating an electronic substrate for use in a photovoltaic module, the method comprising:
embedding a base of said electronic substrate comprising a plurality of path options;
forming one or more conductive pads over said base, such that pad spaces are created between adjacent conductive pads, wherein said conductive pads are configured to receive one or more photovoltaic strips, said conductive pads are electrically connected with at least one of said path options; and
forming one or more bond pads over said base, wherein said bond pads provide an interface to connect said photovoltaic strips to said path options in a predefined manner.

43. The method of claim 42 further comprising connecting said photovoltaic strips to said bond pads.

44. The method of claim 42, wherein said pad spaces are configured to receive one or more optical vees for concentrating solar energy over said photovoltaic strips.

45. A method of fabricating a system for generating electricity from solar energy, said method comprising:
manufacturing a photovoltaic module comprising:
forming one or more conductive pads over an electronic substrate, such that pad spaces are created between adjacent conductive pads, wherein said electronic substrate provides a base with a plurality of path options, said conductive pads being electrically connected with at least one of said path options;
forming one or more bond pads over said base;
arranging one or more photovoltaic strips over said conductive pads, such that cavities are formed over said photovoltaic strips, said photovoltaic strips being capable of converting solar energy into electrical energy, wherein said bond pads provide an interface to connect said photovoltaic strips to said path options in a predefined manner;
placing one or more optical vees in said pad spaces, such that a plurality of cavities is formed between said optical vees, said optical vees being capable of directing solar energy to said photovoltaic strips; and
connecting said photovoltaic strips to said bond pads; and
connecting a power-consuming unit with said photovoltaic module, said consuming unit consuming charge generated by said photovoltaic module.

46. The method of claim 45 further comprising connecting a charge controller with said power-consuming unit, said charge controller controlling the amount of charge in said power-consuming unit.

47. The method of claim 45 further comprising connecting an inverter with said power-consuming unit, said inverter converting electricity from a first form to a second form, wherein electricity is generated by flow of charge stored in said power-consuming unit.

48. The method of claim 47, wherein said first form and said second form are selected from the group consisting of direct current and alternating current.

49. A photovoltaic module for generating electricity from solar energy, said photovoltaic module comprising:
an electronic substrate for providing support to said photovoltaic module, said electronic substrate comprising:
a base for providing a plurality of path options;
one or more conductive pads formed over said base, such that pad spaces are created between adjacent conductive pads, said conductive pads being electrically connected with at least one of said path options;
one or more bond pads formed over said base;
one or more photovoltaic strips arranged over said conductive pads, said photovoltaic strips being capable of converting solar energy into electrical energy, wherein said bond pads provide an interface to connect said photovoltaic strips to said path options in a predefined manner;
one or more optical vees placed over said pad spaces, such that a plurality of cavities is formed between adjacent optical vees, wherein said optical vees comprise a first medium; and
a second medium, said second medium underlying said first medium such that a ratio of a refractive index of said first medium to a refractive index of said second medium is greater than one;
one or more connectors for connecting said photovoltaic strips to said bond pads;
one or more concentrating elements, said concentrating elements being capable of concentrating solar energy over said photovoltaic strips, wherein refractive index of said concentrating elements and said first medium of said optical vees is greater than the refractive index of air or vacuum; and
a transparent member positioned over said optical vees, wherein said transparent member is sealed with said electronic substrate.

50. A photovoltaic module for generating electricity from solar energy, said photovoltaic module comprising:
an electronic substrate for providing support to said photovoltaic module, said electronic substrate comprising:
a base for providing a plurality of path options;
one or more conductive pads formed over said base, such that pad spaces are created between adjacent conductive pads, said conductive pads being electrically connected with at least one of said path options;
one or more bond pads formed over said base;
one or more photovoltaic strips arranged over said conductive pads, said photovoltaic strips being capable of converting solar energy into electrical energy, wherein said bond pads provide an interface to connect said photovoltaic strips to said path options in a predefined manner;
one or more optical vees placed over said pad spaces, such that a plurality of cavities is formed between adjacent optical vees, wherein said optical vees comprise a reflective layer or surface, such that rays incident on said reflective layer or surface are reflected towards said photovoltaic strips;
one or more connectors for connecting said photovoltaic strips to said bond pads; and
a transparent member positioned over said optical vees, wherein said transparent member is sealed with said electronic substrate, and said electronic substrate, said photovoltaic strips, said optical vees and said transparent member form said photovoltaic module in an integrated manner.
